(19) United States
(12) Patent Application Publication
(10) Pub. No.: US 2026/0333856 A1
(43) Pub. Date: Oct. 22, 2026

(54) SEMICONDUCTOR DEVICE

(71) Applicant: Samsung Electronics Co., Ltd., Suwon-si (KR)

(72) Inventors: Jaemin Kim, Suwon-si (KR); Younggun Ko, Suwon-si (KR); Wookhyun Kwon, Suwon-si (KR); Jinkyu Kim, Suwon-si (KR); Byeolhae Eom, Suwon-si (KR); Hyungbin Wang, Suwon-si (KR); Keun Hwi Cho, Suwon-si (KR)

(73) Assignee: Samsung Electronics Co., Ltd., Suwon-si (KR)

(21) Appl. No.: 19/350,620

(22) Filed: Oct. 6, 2025

(30) Foreign Application Priority Data
Apr. 21, 2025 (KR) 10-2025-0051850

(51) Int. Cl. H10D 84/85; H10D 84/01

(52) U.S. Cl. CPC H10D 84/851; H10D 84/0186

(57) ABSTRACT

A semiconductor device according to embodiments includes: a substrate; a first channel structure and a second channel structure on the substrate; a gate structure surrounding the first channel structure and the second channel structure; first source/drain patterns connected to opposite sides of the first channel structure and including an N-type impurity; second source/drain patterns connected to opposite sides of the second channel structure and including a P-type impurity; a first power rail connected to an upper region of one of the first source/drain patterns; a second power rail connected to a lower region of the one of the first source/drain patterns; and a third power rail connected to an upper region or a lower region of one of the second source/drain patterns.

### CROSS-REFERENCE TO RELATED APPLICATIONS

This present application claims priority to and the benefit under 35 U.S.C. § 119(a)-(d) of Korean Patent Application No. 10-2025-0051850, filed on Apr. 21, 2025, in the Korean Intellectual Property Office, the entire disclosure of which is incorporated herein by reference.

### FIELD

The present disclosure relates to a semiconductor device.

### BACKGROUND

A semiconductor device is used in various electronic devices such as a storage device that stores data and a processor that performs calculation processing of data. As electronics industry develops, various methods have been studied to improve various characteristics such as a degree of integration, reliability, a speed, and a function of the semiconductor device. For example, the semiconductor device with a three-dimensional structure has been proposed to overcome limitation due to a reduction in a size of the semiconductor device.

Research has recently been conducted to improve routing congestion and scale a size of the semiconductor device by disposing a power delivery network for routing signals provided to the semiconductor device on a back surface of a substrate.

### SUMMARY

A problem to be solved by the present disclosure is intended to provide a semiconductor device with an improved electrical characteristic.

Problems to be solved by the present disclosure are not limited to the problem, and other technical problems not mentioned may be clearly understood by those skilled in the art from a description of the present disclosure below.

A semiconductor device according to embodiments of the present disclosure includes: a substrate; a first channel structure and a second channel structure disposed above the substrate; a gate structure surrounding the first channel structure and the second channel structure; first source/drain patterns connected to opposite sides of the first channel structure and including an N-type impurity; second source/drain patterns connected to opposite sides of the second channel structure and including a P-type impurity; a first power rail connected to an upper region of one of the first source/drain patterns; a second power rail connected to a lower region of the one of the first source/drain patterns; and a third power rail connected to an upper region or a lower region of one of the second source/drain patterns.

A semiconductor device according to embodiments includes: a substrate; a first channel structure and a second channel structure on the substrate; a gate structure surrounding the first channel structure and the second channel structure; first source/drain patterns connected to opposite sides of the first channel structure and including an N-type impurity; second source/drain patterns connected to opposite sides of the second channel structure and including a P-type impurity; a fourth power rail connected to an upper region or a lower region of one of the first source/drain patterns; a fifth power rail connected to an upper region of one of the second source/drain patterns; a sixth power rail connected to a lower region of the one of the second source/drain patterns; and a first connection pattern disposed between the one of the second source/drain patterns and the sixth power rail.

A semiconductor device according to embodiments includes: a substrate; a first channel structure and a second channel structure on the substrate; a gate structure surrounding the first channel structure and the second channel structure; first source/drain patterns connected to opposite sides of the first channel structure and including an N-type impurity; second source/drain patterns connected to opposite sides of the second channel structure and including a P-type impurity; a fifth power rail disposed on one of the second source/drain patterns; an upper contact via disposed between the one of the second source/drain patterns and the fifth power rail; a sixth power rail disposed below the substrate; a lower contact via disposed on an upper surface of the sixth power rail; a third lower contact electrode disposed between the one of the second source/drain patterns and the lower contact via; and a first connection pattern disposed between the one of the second source/drain patterns and the third lower contact electrode. wherein the second source/drain patterns include silicon germanium, and the first connection pattern includes germanium.

A method for manufacturing a semiconductor device according to embodiments includes: forming a first channel structure and a second channel structure on a substrate; forming a gate structure surrounding the first channel structure and the second channel structure; forming first source/drain patterns including an N-type impurity at opposite sides of the first channel structure; forming second source/drain patterns including a P-type impurity at opposite sides of the second channel structure; forming a first power rail connected to an upper region of one of the first source/drain patterns on the first source/drain patterns; forming a second power rail connected to a lower region of the one of the first source/drain patterns below the first source/drain patterns; and forming a third power rail connected to a lower region of one of the second source/drain patterns below the second source/drain patterns.

The method may further include forming a first connection pattern between the one of the second source/drain patterns and the third power rail before the third power rail is formed.

The first connection pattern may include a material having a lattice constant larger than that of silicon.

The first power rail and the second power rail may be connected to a power source having a same level of voltage.

The method may further include forming an upper contact electrode between the one of the first source/drain patterns and the first power rail and forming a first lower contact electrode in contact with the lower region of the one of the first source/drain patterns. wherein the first source/drain patterns may include silicon (Si), and the first lower contact electrode may include a material having a larger coefficient of thermal expansion than that of silicon.

According to embodiments, a semiconductor device with an improved electrical characteristic may be provided.

### BRIEF DESCRIPTION OF THE DRAWINGS

FIG. 1 is a plan view showing a semiconductor device according to embodiments.

FIG. 2 is a cross-sectional view of the semiconductor device along a line I1-I1′ of FIG. 1.

FIG. 3 is a cross-sectional view of the semiconductor device along a line I2-I2′ of FIG. 1.

FIG. 4 is a cross-sectional view of the semiconductor device along a line I3-I3′ of FIG. 1.

FIG. 5 is a view for describing a semiconductor device according to embodiments.

FIG. 6 is a view for describing a semiconductor device according to embodiments.

FIG. 7 is a view for describing a semiconductor device according to embodiments.

FIG. 8 is a plan view showing a semiconductor device according to embodiments.

FIG. 9 is a cross-sectional view of the semiconductor device along a line I4-I4′ of FIG. 8.

FIG. 10 is a cross-sectional view of the semiconductor device along a line I5-I5′ of FIG. 8.

FIG. 11 is a cross-sectional view of the semiconductor device along a line I6-I6′ of FIG. 8.

FIG. 12 is a view for describing a semiconductor device according to embodiments.

FIG. 13 is a view for describing a semiconductor device according to embodiments.

FIG. 14 is a cross-sectional view of a semiconductor device according to embodiments corresponding to a cross-section cut along the line I1-I1′ of FIG. 1.

FIG. 15 is a cross-sectional view of a semiconductor device according to embodiments corresponding to a cross-section cut along the line I2-I2′ of FIG. 1.

FIGS. 16 to 33 are views for describing a method for manufacturing a semiconductor device according to embodiments.

### DETAILED DESCRIPTION

Embodiments of the present disclosure will be described more fully hereinafter with reference to the accompanying drawings so that those skilled in the art could easily implement the embodiments. The present disclosure may be modified in various ways, all without departing from the spirit or scope of the present disclosure.

In order to clearly describe the present disclosure, parts or portions that are irrelevant to the description are omitted, and identical or similar constituent elements throughout the specification are denoted by the same reference numerals.

In the drawings, each element's size and thickness are arbitrarily illustrated for ease of description, but the present disclosure is not necessarily limited to those illustrated in the drawings. In the drawings, the thicknesses of some layers and areas are exaggerated for clarity. In the drawings, for ease of description, the thicknesses of some layers and areas are exaggerated.

It should be understood that when an element such as a layer, a film, a region, or a plate is referred to as being “on” or “above” another element, it may be directly on the other element, or an intervening element may also be present. In contrast, when an element is referred to as being “directly on” another element, there is no intervening element present. Further, in the specification, the word “on” or “above” means disposed on or below a referenced part, and does not necessarily mean disposed on the upper side of the referenced part based on a gravitational direction.

Unless explicitly stated to the contrary, the word “comprise” and variations such as “comprises” and “comprising” should be understood to imply the inclusion of stated elements but not the exclusion of any other elements.

Throughout the specification, the phrase “in a plan view” or “on a plane” may mean when an object portion is viewed from above, and the phrase “in a cross-sectional view” or “on a cross-section” may mean when a cross-section taken by vertically cutting an object portion is viewed from the side.

In the drawings relating to a semiconductor device according to embodiments, a gate all around (GAA) multi-bridge channel field effect transistor (MBCFETTM) including a nanowire or a nanosheet is illustrated as an example, but the present disclosure is not limited thereto. According to embodiments, the semiconductor device may include a fin-type transistor (FinFET) including a channel structure with a fin-type pattern shape, a tunneling transistor (e.g., a tunneling FET), a 3D stack field effect transistor (3D-SFET) structure, and a complementary field effect transistor (CFET) structure.

Hereinafter, a semiconductor device according to embodiments will be described with reference to the drawings.

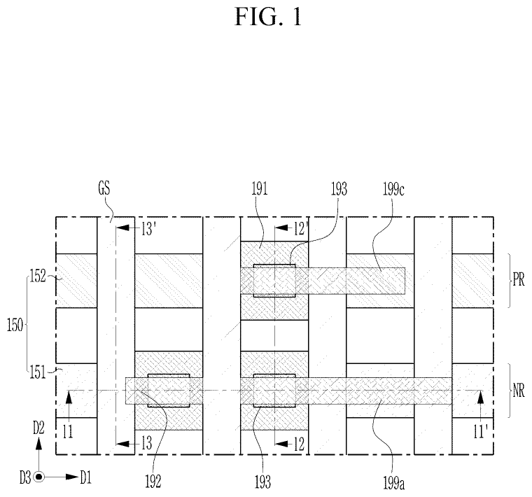

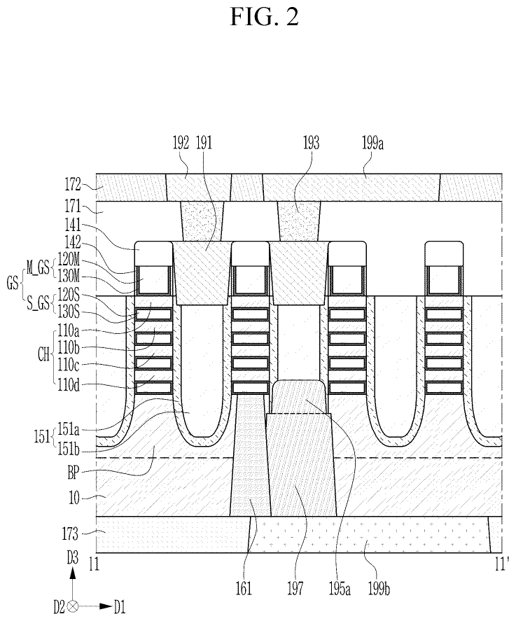

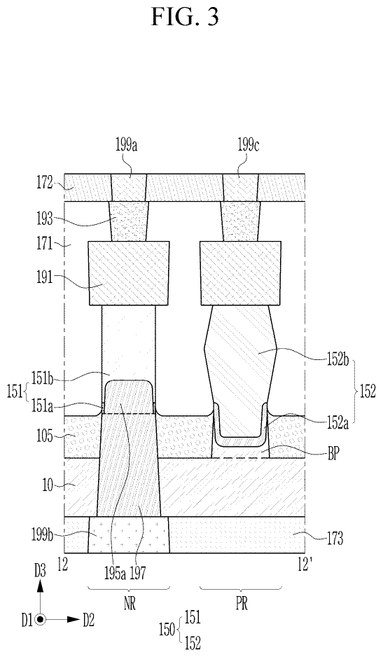

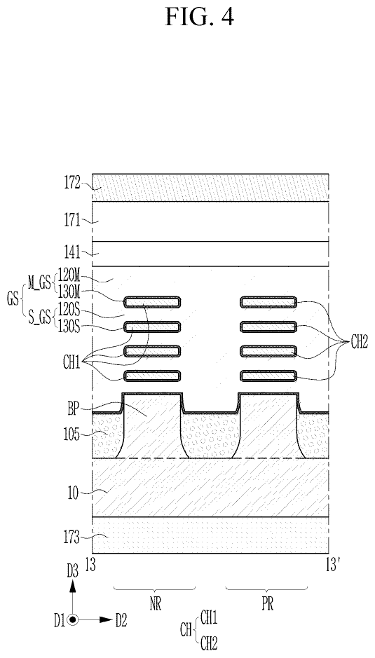

FIG. 1 is a plan view showing a semiconductor device according to embodiments, FIG. 2 is a cross-sectional view of the semiconductor device along a line I1-I1′ of FIG. 1, FIG. 3 is a cross-sectional view of the semiconductor device along a line I2-I2′ of FIG. 1, and FIG. 4 is a cross-sectional view of the semiconductor device along a line I3-I3′ of FIG. 1.

Referring to FIGS. 1 to 4, the semiconductor device according to embodiments may include a substrate 10, a first channel structure CH1 and a second channel structure CH2 disposed above the substrate 10, a gate structure GS surrounding the first channel structure CH1 and the second channel structure CH2, first source/drain patterns 151 connected to opposite sides of the first channel structure CH1 and including an N-type impurity, second source/drain patterns 152 connected to opposite sides of the second channel structure CH2 and including a P-type impurity, a first power rail 199a connected to an upper region of one of the first source/drain patterns 151, a second power rail 199b connected to a lower region of one of the first source/drain patterns 151, and a third power rail 199c connected to an upper region or a lower region of one of the second source/drain patterns 152.

The substrate 10 may be a silicon-on-insulator (SOI) or bulk silicon. Alternatively, the substrate 10 may be a silicon substrate, or may include another material such as silicon germanium (SiGe), a silicon germanium on insulator (SGOI), indium antimony, a lead telluride compound, indium arsenide, indium phosphide, gallium arsenide, or gallium antimony, but the present disclosure is not limited thereto.

In embodiments, the substrate 10 may be an insulating substrate. The substrate 10 may include oxide, nitride, oxynitride, or a combination thereof. For example, the substrate 10 may include silicon nitride (SiNₓ). The substrate 10 is illustrated as a single film, but this is only for convenience of description and the present disclosrue is not limited thereto.

A first surface and a second surface of the substrate 10 may be formed as a plane parallel to a first direction D1 and a second direction D2 intersecting the first direction D1. For example, the first surface of the substrate 10 may be an upper surface, and the second surface of the substrate 10 may be a lower surface. An upper surface of the substrate 10 may be a surface opposite a lower surface of the substrate 10 in a third direction D3. The third direction D3 may be a direction perpendicular to the first direction D1 and the second direction D2. The lower surface of the substrate 10 may be referred to as a back side of the substrate 10. In some embodiments, a logic circuit of a cell region may be implemented on the upper surface of the substrate 10.

The semiconductor device according to embodiments may further include lower patterns BP disposed on the substrate 10. The lower patterns BP may be portions protruding from the first surface of the substrate 10 in the third direction D3. The lower patterns BP may be formed by etching a portion of the substrate 10, or may be grown from the substrate 10 through an epitaxial growth method.

The lower patterns BP may extend in the first direction D1. The lower patterns BP may be disposed to be spaced apart from each other in the second direction D2 on the first surface of the substrate 10. Referring to FIGS. 1 to 4, each of the lower patterns BP may be disposed in one of an NMOSFET region NR and a PMOSFET region PR. The NMOSFET region NR may be a region where an N-type transistor structure (e.g., an N-type MOSFET structure) is disposed, and the PMOSFET region PR may be a region where a P-type transistor structure (e.g., a P-type MOSFET structure) is disposed. Referring to FIG. 3, one among two lower patterns BP disposed to be spaced apart from each other along the second direction D2 may be disposed in the NMOSFET region NR and the other among the two lower patterns BP disposed to be spaced apart from each other along the second direction D2 may be disposed in the PMOSFET region PR, but the present disclosure is not limited thereto. The first source/drain pattern 151 to be described later may be disposed on the lower pattern BP disposed in the NMOSFET region NR. The first source/drain pattern 151 may include an N-type impurity. For example, the first source/drain pattern 151 may be doped with the N-type impurity. The second source/drain pattern 152 to be described later may be disposed on the lower pattern BP disposed in the PMOSFET region PR. The second source/drain pattern 152 may include a P-type impurity. For example, the second source/drain pattern 152 may be doped with the P-type impurity. Unlike those shown in FIGS. 1 to 4, the N-type transistor structure or the P-type transistor structure may be disposed on the two lower patterns BP disposed to be spaced apart from each other along the second direction D2.

The lower patterns BP may include an element semiconductor material such as silicon (Si) or germanium (Ge). Alternatively, the lower patterns BP may include a compound semiconductor. For example, the lower patterns BP may include a group IV-IV compound semiconductor or a group III-V compound semiconductor. For example, the group IV-IV compound semiconductor may be a binary compound or a ternary compound including carbon (C), silicon (Si), germanium (Ge), tin (Sn), or a combination thereof. For example, the group III-V compound semiconductor may be a binary compound, a ternary compound, or a quaternary compound formed by combining a group III element such as aluminum (Al), gallium (Ga), indium (In), or a combination thereof with a group V element such as phosphorus (P), arsenic (As), antimony (Sb), or a combination thereof.

Channel structures CH may be disposed above the first surface of the substrate 10. As shown in FIG. 2 and FIG. 3, if the lower pattern BP is disposed on the substrate 10, the channel structures CH may be disposed above the lower pattern BP. The semiconductor device according to embodiments may include a plurality of channel structures CH disposed to be spaced apart from each other along the second direction D2. Referring to FIG. 4, the first channel structure CH1 and the second channel structure CH2 may be disposed to be spaced apart from each other along the second direction D2. The first channel structure CH1 and the second channel structure CH2 may be disposed above the two lower patterns BP disposed to be spaced apart from each other along the second direction D2. Referring to FIG. 4, the first channel structure CH1 may be disposed above the lower pattern BP disposed in the NMOSFET region NR, and the second channel structure CH2 may be disposed above the lower pattern BP disposed in the PMOSFET region PR. In embodiments, the first source/drain patterns 151 to be described later may be disposed at opposite sides of the first channel structure CH1, and the second source/drain patterns 152 to be described later may be disposed at opposite sides of the second channel structure CH2.

Referring to FIG. 1 and FIG. 2, the channel structures CH may be disposed to be spaced apart from each other in the first direction D1 above the substrate 10 and/or the lower pattern BP. Each of the channel structures CH may include a first channel pattern 110a, a second channel pattern 110b, a third channel pattern 110c, and a fourth channel pattern 110d. A plurality of channel patterns 110a, 110b, 110c, and 110d may be disposed to be spaced apart from each other in the third direction D3. For example, each of the plurality of channel patterns 110a, 110b, 110c, and 110d may have a sheet shape. Each of the channel patterns 110a, 110b, 110c, and 110d may be a nanosheet having a thickness of several nanometers along the third direction D3.

The channel structures CH may provide a path through which an electric current flows between source/drain patterns 150 that will be described below. Referring to FIG. 2 and FIG. 4, the channel structures CH may be disposed between the source/drain patterns 150 to connect the source/drain patterns 150. The channel structures CH may penetrate a portion of the gate structure GS in a direction (e.g., the first direction D1) that intersects a direction in which the gate structure GS described below extends. In FIG. 2 and FIG. 4, four channel patterns 110a, 110b, 110c, and 110d of the channel structures CH are disposed to be spaced apart from each other in the third direction D3, but the present disclosure is not limited thereto, and the number of stacked channel patterns included in one channel structure CH may be variously changed.

The channel structures CH may include a semiconductor material. For example, the channel structures CH may include a group IV semiconductor such as Si or Ge, a group III-V compound semiconductor, a group II-VI compound semiconductor, or the like. In embodiments, the lower pattern BP may be disposed at a lower portion of the channel structure CH. For example, the lower pattern BP may be disposed between a sub-gate structure S_GS disposed at a lowermost portion among a plurality of sub-gate structures S_GS described below and the substrate 10. An upper surface of the lower pattern BP may be in contact with a lower surface of the sub-gate structure S_GS disposed at the lowermost portion among the plurality of sub-gate structures S_GS.

In embodiments, unlike those illustrated in FIGS. 2 to 4, the semiconductor device may not include the lower pattern BP. In this case, the lower surface of the sub-gate structure S_GS disposed at the lowermost portion among the plurality of sub-gate structures S_GS may be directly in contact with the substrate 10.

The semiconductor device according to embodiments may further include a field insulating layer 105 disposed on the substrate 10. The field insulating layer 105 may be disposed between two lower patterns BP adjacent to each other in the second direction D2. The field insulating layer 105 may not be disposed on an upper surface of the lower pattern BP.

The field insulating layer 105 may be disposed on an upper surface of the substrate 10 and side surfaces of the lower patterns BP. The field insulating layer 105 may entirely cover the side surface of the lower pattern BP. Unlike embodiments shown in the drawings, the field insulating layer 105 may cover a portion of the side surface of the lower pattern BP. In this case, a portion of the lower pattern BP may protrude further in the third direction D3 than an upper surface of the field insulating layer 105.

For example, the field insulating layer 105 may include oxide, nitride, oxynitride, or a combination thereof. The field insulating layer 105 is illustrated as a single film, but this is only for convenience of description and the present disclosrue is not limited thereto.

The gate structure GS may be disposed above the substrate 10. The lower pattern BP or the field insulating layer 105 may be disposed between the gate structure GS and the substrate 10. The gate structure GS may extend above the substrate 10 in a direction different from a direction in which the lower pattern BP extends. For example, the gate structure GS may extend above the substrate 10 in a direction (e.g., the second direction D2) that intersects the direction in which the lower pattern BP extends. The gate structure GS may be disposed above the substrate 10. Gate structures GS may be disposed to be spaced apart from each other in the first direction D1. The gate structure GS may include the sub-gate structure S_GS and a main gate structure M_GS. The sub-gate structure S_GS may be disposed above the substrate 10, and the main gate structure M_GS may be disposed on the sub-gate structure S_GS. As shown in the cross-sectional view in FIG. 4, the main gate structure M_GS may be disposed above the field insulating layer 105. A side surface of the sub-gate structure S_GS may be covered by a portion of the main gate structure M_GS disposed above the field insulating layer 105. The sub-gate structure S_GS may not be disposed above the field insulating layer 105. That is, the sub-gate structure S_GS may not be disposed between the main gate structure M_GS and the field insulating layer 105.

Each of the sub-gate structures S_GS may include several layers. For example, each of the sub-gate structures S_GS may include a sub-gate electrode 120S and a sub-gate insulating film 130S. The sub-gate structures S_GS and the channel patterns 110a, 110b, 110c, and 110d may be alternately stacked in the third direction D3. In FIG. 2 and FIG. 4, four sub-gate structures S_GS are disposed to be spaced apart from each other in the third direction D3, but the number of sub-gate structures S_GS disposed to be spaced apart from each other is not limited thereto. For example, the gate structure GS may include three sub-gate structures S_GS.

The sub-gate electrode 120S may be disposed above the lower pattern BP. A plurality of sub-gate electrodes 120S may be disposed to be spaced apart from each other above the lower pattern BP. The plurality of sub-gate electrodes 120S and the plurality of channel patterns 110a, 110b, 110c, and 110d may be alternately and repeatedly stacked. At least one of upper and lower surfaces of the plurality of channel patterns 110a, 110b, 110c, and 110d may be covered by the sub-gate electrode 120S. For example, a lower surface of the first channel pattern 110a may be covered by the sub-gate electrode 120S, and an upper surface of the fourth channel pattern 110d may be covered by the sub-gate electrode 120S. Upper and lower surfaces of each of the second channel pattern 110b and the third channel pattern 110c may be covered by the sub-gate electrode 120S.

The sub-gate electrode 120S may include at least one of a metal, a metal alloy, conductive metal nitride, metal silicide, a doped semiconductor material, conductive metal oxide, and conductive metal oxynitride. For example, the sub-gate electrode 120S may may include at least one of titanium nitride (TN), tantalum carbide (TaC), tantalum nitride (TaN), titanium silicon nitride (TiSiN), tantalum silicon nitride (TaSiN), tantalum titanium nitride (TaTiN), titanium aluminum nitride (TiAlN), tantalum aluminum nitride (TaAlN), tungsten nitride (WN), ruthenium (Ru), titanium aluminum (TiAl), titanium aluminum carbonitride (TiAlCN), titanium aluminum carbide (TiAlC), titanium carbide (TiC), tantalum carbonitride (TaCN), tungsten (W), aluminum (Al), copper (Cu), cobalt (Co), titanium (Ti), tantalum (Ta), nickel (Ni), platinum (Pt), nickel-platinum (Ni—Pt), niobium (Nb), niobium nitride (NbN), niobium carbide (NbC), molybdenum (Mo), molybdenum nitride (MoN), molybdenum carbide (MoC), tungsten carbide (WC), rhodium (Rh), palladium (Pd), iridium (Ir), osmium (Os), silver (Ag), gold (Au), zinc (Zn), vanadium (V), and a combination thereof, but the present disclosure is not limited thereto. The conductive metal oxide and the conductive metal oxynitride may include an oxidized form of the material described above, but the present disclosure is not limited thereto.

The sub-gate insulating film 130S may be disposed along a circumference of the plurality of channel patterns 110a, 110b, 110c, and 110d. The sub-gate insulating film 130S may be in direct contact with the plurality of channel patterns 110a, 110b, 110c, and 110d. The sub-gate insulating film 130S may be interposed between the plurality of channel patterns 110a, 110b, 110c, and 110d and the sub-gate electrode 120S. The sub-gate insulating film 130S may include various insulating materials. Although not explicitly disclosed in FIG. 2 and FIG. 3, the semiconductor device according to embodiments may further include an inner gate spacer disposed between the sub-gate insulating film 130S and a source/drain pattern 150 described below.

In embodiments, the sub-gate insulating film 130S is illustrated as a single film, but the present disclosure is not limited thereto. For example, the sub-gate insulating film 130S may be formed of a multi-film including silicon oxide (SiO₂) and a high dielectric constant material. In this case, the high dielectric constant material may include a material having a higher dielectric constant than that of the silicon oxide (SiO₂) such as hafnium oxide (HfO), aluminum oxide (AlO), or tantalum oxide (TaO).

The main gate structure M_GS may be disposed on the sub-gate structure S_GS and the plurality of channel patterns 110a, 110b, 110c, and 110d. The main gate structure M_GS may be disposed on an upper surface of the channel pattern 110a disposed at an uppermost portion among the plurality of channel patterns 110a, 110b, 110c, and 110d. The main gate structure M_GS may be disposed above the field insulating layer 105. The main gate structure M_GS may cover opposite side surfaces of the sub-gate structure S_GS.

The main gate structure M_GS may include a main gate electrode 120M and a main gate insulating film 130M.

The main gate electrode 120M may be disposed on the sub-gate structure S_GS and the plurality of channel patterns 110a, 110b, 110c, and 110d. The main gate electrode 120M may extend in a direction intersecting the lower pattern BP. At least a portion of the main gate electrode 120M may be disposed on a structure in which the sub-gate electrode 120S and the plurality of channel patterns 110a, 110b, 110c, and 110d are alternately stacked. The remaining portion of the main gate electrode 120M may cover a side surface of the structure in which the sub-gate electrode 120S and the plurality of channel patterns 110a, 110b, 110c, and 110d are alternately stacked. Four surfaces of each of the plurality of channel patterns 110a, 110b, 110c, and 110d may be surrounded by the sub-gate electrode 120S and/or the main gate electrode 120M.

The main gate electrode 120M may include the same material as that of the sub-gate electrode 120S. For example, the main gate electrode 120M may include at least one of a metal, a metal alloy, conductive metal nitride, metal silicide, a doped semiconductor material, conductive metal oxide, and conductive metal oxynitride.

The main gate insulating film 130M may extend along a side surface of the main gate electrode 120M. The main gate insulating film 130M may extend along a side surface of a gate spacer 142 described later. The main gate insulating film 130M may include various insulating materials. The main gate insulating film 130M may include the same material as that of the sub-gate insulating film 130S.

In embodiments, the main gate insulating film 130M is illustrated as a single film, but the present disclosure is not limited thereto. For example, the main gate insulating film 130M may be formed of a multi-film including silicon oxide (SiO₂) and a high dielectric constant material. In this case, the high dielectric constant material may include a material having a higher dielectric constant than that of the silicon oxide (SiO₂) such as hafnium oxide (HfO), aluminum oxide (AlO), or tantalum oxide (TaO).

The semiconductor device according to embodiments may further include a capping layer 141 and the gate spacer 142.

The gate spacer 142 may be disposed on a side surface of the main gate electrode 120M. The gate spacer 142 may be disposed on the channel structure CH. The gate spacer 142 may not be disposed on a side surface of the sub-gate electrode 120S. The gate spacer 142 may not be disposed on a side surface of each of the channel patterns 110a, 110b, 110c, and 110d. The gate spacer 142 may not be disposed between the lower pattern BP and the plurality of channel patterns 110a, 110b, 110c, and 110d. The gate spacer 142 may not be disposed between the plurality of channel patterns 110a, 110b, 110c, and 110d adjacent in the third direction D3. The gate spacer 142 is illustrated as a single film, but this is only for convenience of description and the present disclosrue is not limited thereto.

For example, the gate spacer 142 may include at least one of silicon nitride (SiN_{X}), silicon oxynitride (SiON), silicon oxide (SiO₂), silicon oxycarbonitride (SiOCN), silicon boron nitride (SiBN), silicon oxyboron nitride (SiOBN), silicon oxycarbide (SiOC), and a combination thereof. The gate spacer 142 is illustrated as a single film, but this is only for convenience of description and the present disclosrue is not limited thereto.

The capping layer 141 may be disposed on the main gate structure M_GS and the gate spacer 142. Upper surface and side surfaces of the capping layer 141 may be covered by an interlayer insulating layer 171 described later. Unlike embodiments shown in the drawings, the capping layer 141 may be disposed between gate spacers 142.

For example, the capping layer 141 may include at least one of silicon nitride (SN), silicon oxynitride (SiON), silicon (Si), silicon carbonitride (SiCN), silicon oxycarbonitride (SiOCN), and a combination thereof. The capping layer 141 may include a material having an etching selectivity with respect to the interlayer insulating layer 171 described later.

The source/drain patterns 150 may be disposed above the substrate 10. The lower pattern BP may be disposed between the source/drain patterns 150 and the substrate 10. However, the present disclosure is not limited thereto, and the lower pattern BP may not be disposed between the source/drain pattern 150 and the substrate 10. The channel structure CH and the gate structure GS may be disposed between the source/drain patterns 150. In other words, a plurality of source/drain patterns 150 and the plurality of channel structures CH may be alternately disposed along the first direction D1 in which the lower pattern BP extends.

In embodiments, each of the source/drain patterns 150 may extend inside the lower pattern BP along the third direction D3. Referring to FIG. 2, the source/drain patterns 150 may extend further downward than a lower surface of the gate structure GS. Referring to FIG. 2, the lower pattern BP may be disposed between two source/drain patterns 150 disposed to be spaced apart from each other in the first direction D1. A level of a lower surface of the source/drain pattern 150 may be lower than a level of the lower surface of the gate structure GS. For example, the lower surface of the source/drain pattern 150 may be disposed at a lower level than that of the lower surface of the sub-gate electrode 120S disposed at a lowermost portion among the plurality of sub-gate electrodes 120S disposed to be spaced apart from each other in the third direction D3 on the lower pattern BP.

Referring to FIGS. 2 to 4, the lower surface of the source/drain pattern 150 may be disposed at a higher level than that of an upper surface of the substrate 10. In other words, the source/drain pattern 150 may extend to a level higher than that of the upper surface of the substrate 10. The source/drain pattern 150 may not extend to a level lower than that of the upper surface of the substrate 10.

The lower surface of the source/drain pattern 150 may be disposed at a lower level than that of an upper surface of the field insulating layer 105. Referring to FIG. 3, the source/drain pattern 150 may include a region overlapping the field insulating layer 105 in the second direction D2. A region extending inside the lower pattern BP among an entire region of the source/drain pattern 150 may overlap the field insulating layer 105 in the second direction D2. In a region where the source/drain pattern 150 and the field insulating layer 105 overlap, the lower pattern BP may be disposed between the source/drain pattern 150 and the field insulating layer 105. At least some regions of each of the source/drain patterns 150 may be surrounded by the lower pattern BP. For example, referring to FIG. 2, each of the source/drain patterns 150 may extend inside the lower pattern BP along the third direction D3, and a side surface and a lower surface of the region extending inside the lower pattern BP may be surrounded by the lower pattern BP. In embodiments, at least a portion of a side surface and a lower surface of the source/drain pattern 150 may be in contact with the lower pattern BP.

The source/drain patterns 150 may be disposed in the second direction D2. Referring to FIG. 1 and FIG. 3, a plurality of lower patterns BP may be disposed to be spaced apart from each other along the second direction D2 on the substrate 10, and the source/drain patterns 150 may be disposed on each of the lower patterns BP. The semiconductor device according to embodiments may include the first source/drain pattern 151 and the second source/drain pattern 152. The first source/drain pattern 151 and the second source/drain pattern 152 may be disposed to be spaced apart from each other along the second direction D2. In embodiments, two source/drain patterns 151 and 152 disposed to be spaced apart from each other along the second direction D2 may be doped with different types of impurities. In embodiments, the first source/drain pattern 151 and the second source/drain pattern 152 may be doped with different types of impurities. For example, the first source/drain pattern 151 and the second source/drain pattern 152 may be doped with one of an N-type impurity and a P-type impurity. For example, the first source/drain pattern 151 may be doped with the N-type impurity, and the second source/drain pattern 152 may be doped with the P-type impurity. For example, referring to FIG. 3, the first source/drain pattern 151 may be disposed in the NMOSFET region NR, and the second source/drain pattern 152 may be disposed in the PMOSFET region PR.

The source/drain pattern 150 may be disposed at opposite sides of the channel structure CH or at opposite sides of the sub-gate structure S_GS. For example, two source/drain patterns 150 disposed on one lower pattern BP may be disposed to be spaced apart from each other in a direction (e.g., the first direction D1) intersecting a direction in which the gate structure GS extends with the channel structure CH or the sub-gate structure S_GS interposed therebetween. The source/drain pattern 150 may be in direct contact with the channel structure CH or the sub-gate structure S_GS. The source/drain pattern 150 may be in direct contact with the sub-gate insulating film 130S of the sub-gate structure S_GS. Although not shown in the drawings, an inner spacer may be further disposed between the source/drain pattern 150 and the sub-gate insulating film 130S. The inner spacer may include at least one of silicon nitride (SiN_{X}), silicon oxynitride (SiON), silicon oxide (SiO₂), silicon oxycarbonitride (SiOCN), silicon boron nitride (SiBN), silicon oxyboron nitride (SiOBN), silicon oxycarbide (SiOC), and a combination thereof.

The source/drain pattern 150 may be formed of an epitaxial layer formed by selective epitaxial growth (SEG). In other words, the source/drain patterns 150 may be formed by removing at least some regions of a semiconductor pattern stacked on the lower pattern BP and then using a selective epitaxial growth (SEG) method in the region.

In embodiments, the first source/drain pattern 151 and the second source/drain pattern 152 may have different cross-sectional shapes. In embodiments, a cross-sectional shape of the source/drain pattern 150 may vary depending on a material included in each of the source/drain patterns 150. For example, in a cross-sectional view illustrated in FIG. 3, the first source/drain pattern 151 and the second source/drain pattern 152 may have different cross-sectional shapes. For example, referring to FIG. 3, the first source/drain pattern 151 may have a shape having a constant width in the second direction D2. For example, the second source/drain pattern 152 may have a shape in which a width in the second direction D2 gradually increases and then decreases again as it moves away from the upper surface of the substrate 10 in a region that does not overlap the lower pattern BP in a horizontal direction. Although not explicitly shown in FIG. 3, In embodiments, an upper surface of the first source/drain pattern 151 and an upper surface of the second source/drain pattern 152 may have a flat shape. However, the present disclosure is not limited thereto, and the upper surface of the second source/drain pattern 152 may have a shape in which the width in the second direction D2 gradually decreases as it moves away from the substrate 10.

Each of the source/drain patterns 150 may include each of liner layers 151a and 152a and each of filling layers 151b and 152b. Referring to FIG. 2 and FIG. 3, the first source/drain pattern 151 and the second source/drain pattern 152 may include the filling layers 151b and 152b and the liner layers 151a and 152a. The liner layers 151a and 152a may be disposed outside the filling layers 151b and 152b. Side and lower surfaces of the filling layers 151b and 152b may be surrounded by the liner layers 151a and 152a. The liner layers 151a and 152a may be in direct contact with the sub-gate structure S_GS and the channel structure CH. The filling layers 151b and 152b may be disposed on the liner layers 151a and 152a. The filling layers 151b and 152b and the liner layers 151a and 152a may have upper surfaces having substantially the same height. However, the present disclosure is not limited thereto, and unlike embodiments shown in the drawings in FIG. 2, the filling layers 151b and 152b and the liner layers 151a and 152a may have upper surfaces having different heights in some regions.

In embodiments, the liner layers 151a and 152a may be conformally disposed along an interface between the gate structure GS, the channel structure CH, and the lower pattern BP and each of the liner layers 151a and 152a. The filling layers 151b and 152b may be disposed on inner side surfaces of the liner layers 151a and 152a.

For example, referring to FIG. 2 and FIG. 3, in a region where the source/drain pattern 150 overlaps the channel structure CH and the gate structure GS in the first direction D1, the liner layers 151a and 152a may be disposed between the channel structure CH and the filling layers 151b and 152b and between the gate structure GS and the filling layers 151b and 152b. In a region where the source/drain pattern 150 overlaps the channel structure CH and the gate structure GS in the first direction D1, the liner layers 151a and 152a may extend along side surfaces of the filling layers 151b and 152b.

In a region where the source/drain pattern 150 overlaps the lower pattern BP in the first direction D1 and the second direction D2, the liner layers 151a and 152a may be disposed between the lower pattern BP and the filling layers 151b and 152b. In the region where the source/drain pattern 150 overlaps the lower pattern BP in the first direction D1 and the second direction D2, the liner layers 151a and 152a may extend along side and lower surfaces of the filling layers 151b and 152b. Referring to FIG. 2 and FIG. 3, in the region where the source/drain pattern 150 overlaps the lower pattern BP in the first direction D1 and the second direction D2, the liner layers 151a and 152a may be conformally disposed along an inner side surface and a lower surface of the lower pattern BP. Entire side surface regions of the filling layers 151b and 152b may be surrounded by the liner layers 151a and 152a in a region disposed at a level lower than a level of a lower surface of the gate structure GS.

Referring to FIG. 3, in a cross-sectional view formed in the second direction D2 and the third direction D3, the liner layers 151a and 152a may be disposed on side surfaces of the filling layers 151b and 152b that overlaps the lower pattern BP in the first direction D1, and may not be disposed on the side surfaces of the filling layers 151b and 152b that do not overlap the lower pattern BP in the first direction D1. This may be due to a process characteristic in which the liner layers 151a and 152a are formed through a selective epitaxial growth process using the plurality of channel patterns 110a, 110b, 110c, and 110d and the lower pattern BP as a seed layer.

The source/drain pattern 150 may include a semiconductor material. For example, the source/drain pattern 150 may include silicon (Si) or germanium (Ge). For example, the source/drain pattern 150 may include a binary compound including at least two of carbon (C), silicon (Si), germanium (Ge), and tin (Sn), or a ternary compound. For example, the source/drain pattern 150 may include silicon (Si), silicon germanium (SiGe), germanium (Ge), silicon carbide (SIC), or the like, but the present disclosure is not limited thereto.

In embodiments, the first source/drain pattern 151 and the second source/drain pattern 152 may include different materials. For example, the first source/drain pattern 151 and the second source/drain pattern 152 may include different semiconductor materials. For example, the first source/drain pattern 151 may include silicon (Si), and in embodiments, the first source/drain pattern 151 may not include silicon germanium (SiGe) or germanium (Ge). The second source/drain pattern 152 may include silicon germanium (SiGe). In the second source/drain pattern 152, a liner layer 152a and a filling layer 152b may have different germanium (Ge) contents. For example, a content of germanium (Ge) included in the liner layer 152a may be less than a content of germanium (Ge) included in the filling layer 152b. In this case, a content (e.g., at %) of the germanium within the liner layer 152a may be a content (e.g., at %) of the germanium with respect to 100 at % of the liner layer 152a, and a content (e.g., at %) of the germanium within the filling layer 152b may be a content (e.g., at %) of the germanium with respect to 100 a t% of the filling layer 152b.

In embodiments, the first source/drain pattern 151 and the second source/drain pattern 152 may be doped with different impurities. For example, the first source/drain pattern 151 may be doped with an N-type impurity. For example, if the first source/drain pattern 151 includes silicon (Si), the first source/drain pattern 151 may be doped with at least one of phosphorus (P), arsenic (As), and antimony (Sb), but the present disclosure is not limited thereto.

For example, the second source/drain pattern 152 may be doped with a P-type impurity. For example, if the second source/drain pattern 152 includes the silicon germanium (SiGe), the second source/drain pattern 152 may be doped with at least one of boron (B), gallium (Ga), and indium (In), but the present disclosure is not limited thereto.

In embodiments, at least one of the first source/drain pattern 151 and the second source/drain pattern 152 may be commonly connected to the first power rail 199a and the second power rail 199b to be described later. For example, referring to FIG. 3, the first source/drain pattern 151 may be commonly connected to the first power rail 199a and the second power rail 199b. The first power rail 199a may be connected to an upper region of the first source/drain pattern 151, and the second power rail 199b may be connected to a lower region of the first source/drain pattern 151.

In embodiments, the second source/drain pattern 152 may be connected only to the third power rail 199c. Referring to FIG. 3, the third power rail 199c may be connected to an upper region of the second source/drain pattern 152. A lower region of the second source/drain pattern 152 may not be connected to the power rails 199a, 199b, and 199c, but the present disclosure is not limited thereto.

The semiconductor device according to embodiments may further include an insulating pattern 161 disposed between two adjacent source/drain patterns 150 below the gate structure GS. The insulating pattern 161 may prevent a leakage current from flowing between the two adjacent source/drain patterns 150.

The insulating pattern 161 may be disposed below the sub-gate structure S_GS. In FIG. 2, only one insulating pattern 161 is illustrated, but in contrast, the semiconductor device according to embodiments may include a plurality of insulating patterns 161. For example, the insulating pattern 161 may be disposed below a lower surface of each of the plurality of sub-gate structures S_GS disposed to be spaced apart from each other along the first direction D1. The insulating pattern 161 may have an upper surface that is in contact with at least some regions of a lower surface of the sub-gate structure S_GS disposed at a lowermost portion among the plurality of sub-gate structures S_GS disposed to be spaced apart from each other in the third direction D3. An upper surface of the insulating pattern 161 may be in contact with at least some regions of the sub-gate insulating film 130S included in the sub-gate structure S_GS disposed at the lowermost portion among the plurality of sub-gate structures S_GS disposed to be spaced apart from each other in the third direction D3.

The insulating pattern 161 may penetrate the substrate 10 and the lower pattern BP in the third direction D3. In embodiments, the insulating pattern 161 may have a shape in which a width in a horizontal direction (e.g., the first direction D1 or the second direction D2) gradually narrows from a lower portion thereof to an upper portion thereof. A side surface of the insulating pattern 161 may be surrounded by the lower pattern BP, the substrate 10, and/or a lower contact via 197 to be described later. The insulating pattern 161 may have a side surface that is in contact with the lower pattern BP and/or the field insulating layer 105. For example, in FIG. 2, both side surfaces of the insulating pattern 161 may be in contact with the lower pattern BP. For example, in FIG. 3, both side surfaces of the insulating pattern 161 may be in contact with the field insulating layer 105. If the semiconductor device according to embodiments does not include the lower pattern BP, the insulating pattern 161 may have a side surface that is in contact with the substrate 10.

A width of the insulating pattern 161 in the first direction D1 may be smaller than a width of the sub-gate structure S_GS in the first direction D1. A width of the insulating pattern 161 in the second direction D2 may be substantially the same as a width of the sub-gate structure S_GS in the second direction D2. However, the present disclosure is not limited thereto, and the width of the insulating pattern 161 in the second direction D2 may be narrower than the width of the sub-gate structure S_GS in the second direction D2.

The insulating pattern 161 may include various insulating materials. The insulating pattern 161 may include at least one of silicon nitride (SiNₓ), silicon oxide (SiOₓ), silicon carbonitride (SiCN), and silicon oxynitride (SiON).

The semiconductor device according to embodiments may further include the interlayer insulating layer 171 covering the source/drain pattern 150 and the gate structure GS. The interlayer insulating layer 171 may be disposed on a side surface of the gate spacer 142 and a side surface and an upper surface of the capping layer 141.

The interlayer insulating layer 171 may be disposed on upper surfaces of the source/drain patterns 150. The interlayer insulating layer 171 may also be disposed on some regions of a side surface of the source/drain pattern 150. Referring to FIG. 2 and FIG. 3, the interlayer insulating layer 171 may cover entire upper and side surfaces of the source/drain patterns 150 in a region that does not overlap the gate structures GS in the third direction D3. The interlayer insulating layer 171 may also be disposed on an upper surface of the field insulating layer 105.

For example, the interlayer insulating layer 171 may include at least one of silicon oxide (SiO₂), silicon nitride (SiN_{X}), silicon oxynitride (SiON), and a low dielectric constant material. For example, the low dielectric constant material may include fluorinated tetraethylorthosilicate (FTEOS), hydrogen silsesquioxane (HSQ), bis-benzocyclobutene (BCB), tetramethylorthosilicate (TMOS), octamethyleyclotetrasiloxane (OMCTS), hexamethyldisiloxane (HMDS), trimethylsilyl (TMSB), diacetoxyditertiarybutosiloxane (DADBS), trimethylsilil phosphate (TMSP), polytetrafluoroethylene (PTFE), tonen silazen (TOSZ), a fluoride silicate glass (FSG), polyimide nanofoams such as polypropylene oxide, carbon doped silicon oxide (CDO), an organo silicate glass (OSG), SILK, amorphous fluorinated carbon, silica aerogels, silica xerogels, mesoporous silica, or a combination thereof, but the present disclosure is not limited thereto. In embodiments, the interlayer insulating layer 171 and the field insulating layer 105 may include different insulating materials. However, the present disclosure is not limited thereto, and in embodiments, the interlayer insulating layer 171 and the field insulating layer 105 may include the same insulating material. In this case, a boundary between the interlayer insulating layer 171 and the field insulating layer 105 may not be recognized.

The semiconductor device according to embodiments may further include an upper contact electrode 191. The upper contact electrode 191 may be disposed on the source/drain pattern 150. The upper contact electrode 191 may extend to the inside of the source/drain pattern 150 by a predetermined depth along the third direction D3. The upper contact electrode 191 may be disposed between two main gate structures M_GS disposed to be spaced apart from each other along the first direction D1. The upper contact electrode 191 may have an inclined side surface in which a width of a lower portion thereof becomes narrower than a width of an upper portion thereof according to an aspect ratio. For example, a width of the upper contact electrode 191 in a horizontal direction may have a shape that gradually narrows as it approaches an upper surface of the source/drain pattern 150.

The semiconductor device according to embodiments may include a plurality of upper contact electrodes 191 connected to the first source/drain pattern 151 and the second source/drain pattern 152. Referring to FIG. 1 and FIG. 3, the semiconductor device according to embodiments may include the first source/drain pattern 151 disposed in the NMOSFET region NR and the second source/drain pattern 152 disposed in the PMOSFET region PR. In embodiments, the upper contact electrode 191 may electrically connect the first source/drain pattern 151 and the first power rail 199a to be described later. In embodiments, the upper contact electrode 191 may electrically connect the second source/drain pattern 152 and the third power rail 199c to be described later.

At least some regions of the upper contact electrode 191 may be surrounded by the interlayer insulating layer 171. Referring to FIG. 2 and FIG. 3, some regions of an upper surface and a side surface of the upper contact electrode 191 may be covered by the interlayer insulating layer 171. In embodiments, some regions of the upper contact electrode 191 extending into the source/drain pattern 150 may be surrounded by the source/drain pattern 150.

Although not shown in FIG. 2 and FIG. 3, the semiconductor device according to embodiments may further include a silicide layer disposed between the upper contact electrode 191 and the source/drain pattern 150. If the semiconductor device according to embodiments does not include the silicide layer, a portion of a side surface and a lower surface of the upper contact electrode 191 may be in contact with the source/drain pattern 150 as illustrated in FIG. 2.

The upper contact electrode 191 may include a conductive material. For example, the upper contact electrode 191 may include at least one of a metal, a metal alloy, conductive metal nitride, metal silicide, a doped semiconductor material, conductive metal oxide, and conductive metal oxynitride.

In embodiments, the upper contact electrode 191 may include a material having a larger coefficient of thermal expansion than that of a material included in the source/drain pattern 150 connected to the upper contact electrode 191. A process of forming the upper contact electrode 191 on the source/drain pattern 150 may be performed at a high temperature. For example, the process of forming the upper contact electrode 191 may be performed at about 300 to 500 °C. If the upper contact electrode 191 includes the material having the larger coefficient of thermal expansion than that of the material included in the source/drain pattern 150, a volume of the upper contact electrode 191 may decrease (e.g., shrink) as the upper contact electrode 191 is formed on the source/drain pattern 150 and then cooled. In this case, a tensile stress may be induced in the first direction D1 in the channel patterns 110a, 110b, 110c, and 110d. If the tensile stress is induced in the channel patterns 110a, 110b, 110c, and 110d, scattering within a lattice of electrons that are majority carriers may be decreased during an on-operation of the N-type transistor structure so that mobility of the electrons is increased. Thus, current driving capability may be improved during an on-operation of the semiconductor device.

In embodiments, the upper contact electrode 191 may be connected to the first source/drain pattern 151. The first source/drain pattern 151 may be disposed in the NMOSFET region NR. In embodiments, the first source/drain pattern 151 may include silicon (Si). The first source/drain pattern 151 may be doped with an N-type impurity. For example, the first source/drain pattern 151 may be doped with at least one of phosphorus (P), arsenic (As), and antimony (Sb). In embodiments, the upper contact electrode 191 may include a material having a greater coefficient of thermal expansion than that of silicon (Si). For example, the upper contact electrode 191 may include at least one of tungsten (W) and molybdenum (Mo).

The semiconductor device according to embodiments may further include an upper contact via 193 disposed on the upper contact electrode 191. The upper contact via 193 may connect at least one of the source/drain patterns 150 to at least one of an upper wiring layer 192, the first power rail 199a, and the third power rail 199c to be described later, together with the upper contact electrode 191. The upper contact via 193 may be in contact with at least a portion of an upper surface of the upper contact electrode 191. A side surface of the upper contact via 193 may be surrounded by the interlayer insulating layer 171.

The upper contact via 193 may include a conductive material. For example, the upper contact via 193 may include at least one of a metal, a metal alloy, conductive metal nitride, metal silicide, a doped semiconductor material, conductive metal oxide, and conductive metal oxynitride.

The semiconductor device according to embodiments may further include an upper insulating layer 172 disposed on the interlayer insulating layer 171. The upper insulating layer 172 may have a lower surface that is in contact with an upper surface of the interlayer insulating layer 171. The upper wiring layer 192 and the first power rail 199a that will be described later may be disposed inside the upper insulating layer 172. The upper insulating layer 172 may surround side surfaces of the upper wiring layer 192 and the first power rail 199a. The upper insulating layer 172 may electrically separate the upper wiring layer 192 from another upper wiring layer 192 adjacent thereto or the power rail 199a.

The upper insulating layer 172 may include an insulating material. For example, the upper insulating layer 172 may include at least one of silicon nitride (SiNₓ), silicon oxide (SiO₂), silicon carbonitride (SiCN), and silicon oxynitride (SiON), but the present disclosure is not limited thereto.

The semiconductor device according to embodiments may further include the upper wiring layer 192 disposed within the upper insulating layer 172. The upper wiring layer 192 may be connected to at least one of the source/drain patterns 150. The upper wiring layer 192 may provide an electrical signal such as a voltage or a current to at least one of the source/drain patterns 150. The upper contact electrode 191 and the upper contact via 193 may be disposed between the upper wiring layer 192 and the source/drain pattern 150. The upper wiring layer 192 may have a lower surface in contact with at least a portion of an upper surface of the upper contact via 193. The upper wiring layer 192 may be connected to at least one of the source/drain patterns 150 by the upper contact electrode 191 and the upper contact via 193.

The first power rail 199a and the third power rail 199c may be disposed within the upper insulating layer 172. The first power rail 199a and the third power rail 199c may be configured to provide electric power to at least one of the source/drain patterns 150. For example, the first power rail 199a and the third power rail 199c may be connected to an external input power source or an output power source to provide the electric power to at least one of the source/drain patterns 150. For example, the first power rail 199a and the third power rail 199c may be connected to a ground. In embodiments, the first power rail 199a and the third power rail 199c may be disposed at a higher level than that of an upper surface of the source/drain pattern 150 and that of an upper surface of the gate structure GS. For example, the first power rail 199a and the third power rail 199c may form at least a portion of a front side power delivery network (FSPDN). Referring to FIG. 1 and FIG. 2, the first power rail 199a and the third power rail 199c may extend along the first direction D1. However, the present disclosure is not limited thereto, and each of the first power rail 199a and the third power rail 199c may extend along the second direction D2.

In embodiments, the first power rail 199a may be connected to the N-type transistor structure. Referring to FIG. 2 and FIG. 3, the first power rail 199a may be connected to the first source/drain pattern 151. The upper contact via 193 and the upper contact electrode 191 may be disposed between the first power rail 199a and the first source/drain pattern 151. The first power rail 199a may be electrically connected to an upper region of the first source/drain pattern 151 by the upper contact via 193 and the upper contact electrode 191.

In embodiments, the third power rail 199c may be connected to the P-type transistor structure. Referring to FIG. 3, the third power rail 199c may be connected to the second source/drain pattern 152. The upper contact via 193 and the upper contact electrode 191 may be disposed between the third power rail 199c and the second source/drain pattern 152. The third power rail 199c may be electrically connected to an upper region of the second source/drain pattern 152 by the upper contact via 193 and the upper contact electrode 191.

The first power rail 199a and the third power rail 199c may include a conductive material. For example, the first power rail 199a and the third power rail 199c may include at least one of a metal, a metal alloy, conductive metal nitride, conductive metal carbide, conductive metal oxide, conductive metal carbonitride, and a two-dimensional (2D) material. The metal may include at least one of copper (Cu), titanium (Ti), tantalum (Ta), tungsten (W), nickel (Ni), cobalt (Co), and platinum (Pt). The conductive metal nitride may include at least one of titanium nitride (TiN), tantalum nitride (TaN), tungsten nitride (WN), nickel nitride (NiN), cobalt nitride (CoN), and platinum nitride (PtN).

The semiconductor device according to embodiments may further include a lower insulating layer 173 disposed below the substrate 10. In embodiments, the lower insulating layer 173 may include the second power rail 199b that will be described later. The lower insulating layer 173 may electrically separate the second power rail 199b from another power rail adjacent thereto. The lower insulating layer 173 may surround at least some regions of a side surface of the second power rail 199b.

The lower insulating layer 173 may include an insulating material. For example, the lower insulating layer 173 may include at least one of silicon oxide (SiO₂), silicon nitride (SiNₓ), and silicon oxynitride (SiON), but the present disclosure is not limited thereto.

The semiconductor device according to embodiments may further include a first lower contact electrode 195a and the lower contact via 197 disposed between the lower insulating layer 173 and the source/drain pattern 150. The first lower contact electrode 195a and the lower contact via 197 may electrically connect at least one of the source/drain patterns 150 and the second power rail 199b. In embodiments, the first lower contact electrode 195a and the lower contact via 197 may be disposed in the NMOSFET region NR. The first lower contact electrode 195a and the lower contact via 197 may not be disposed in the PMOSFET region PR.

The first lower contact electrode 195a and the lower contact via 197 may be disposed between the first source/drain pattern 151 and the second power rail 199b. The first lower contact electrode 195a and the lower contact via 197 may electrically connect the first source/drain pattern 151 and the second power rail 199b.

The lower contact via 197 may extend from an upper surface of the lower insulating layer 173 along the third direction D3 into the substrate 10. The lower contact via 197 may penetrate the substrate 10 in the third direction D3. The lower contact via 197 may have an inclined side surface in which a width of an upper region thereof is narrower than a width of a lower region hereof depending on an aspect ratio. A width of the lower contact via 197 along the first direction D1 may be wider than a width of the source/drain pattern 150 along the first direction D1. Referring to FIG. 2, a width of an upper surface of the lower contact via 197 along the first direction D1 may be wider than the width of the source/drain pattern 150 along the first direction D1.

In embodiments, the lower contact via 197 may penetrate the substrate 10 to further extend into the lower pattern BP along the third direction D3. In a region where the lower contact via 197 overlaps the field insulating layer 105 in the second direction D2, a side surface of the lower contact via 197 may be disposed along a side surface of the field insulating layer 105.

In embodiments, the upper surface of the lower contact via 197 may be disposed at a higher level than that of a lower surface of the source/drain pattern 150. The upper surface of the lower contact via 197 may be disposed between upper and lower surfaces of the source/drain pattern 150. For example, the upper surface of the lower contact via 197 may be disposed at a higher level than that of a lower surface of the source/drain pattern 150 that overlaps the lower contact electrode 195 in the third direction D3 among the source/drain patterns 150 and that of a lower surface of another source/drain pattern 150 adjacent thereto in the first direction D1 or the second direction D2 among the source/drain patterns 150.

The first lower contact electrode 195a may extend from the upper surface of the lower contact via 197 along the third direction D3 into the first source/drain pattern 151. Referring to FIG. 2 and FIG. 3, the first lower contact electrode 195a may have an inclined side surface in which an upper region is narrower than a lower region depending on an aspect ratio. In embodiments, a width of the first lower contact electrode 195a along the first direction D1 may be equal to or narrower than a width of the first source/drain pattern 150 along the first direction D1. In embodiments, a width of the first lower contact electrode 195a along the second direction D2 may be equal to or narrower than a width of the first source/drain pattern 151 along the second direction D2.

In embodiments, an upper surface of the first lower contact electrode 195a may be disposed between a lower surface of the gate structure GS and an upper surface of the first source/drain pattern 151. The upper surface of the first lower contact electrode 195a may be disposed at a level higher than a level of an upper surface of the lower pattern BP. Unlike embodiments illustrated in FIG. 2, the first lower contact electrode 195a may overlap at least one of the channel patterns 110a, 110b, 110c, and 110d in the first direction D1. For example, the first lower contact electrode 195a may overlap the channel pattern 110d disposed at a lowermost portion among the plurality of channel patterns 110a, 110b, 110c, and 110d disposed to be spaced apart from each other in the third direction D3 in the first direction D1. For example, the first lower contact electrode 195a may overlap the channel pattern 110d disposed at the lowermost portion and the channel pattern 110c disposed above the channel pattern 110d in the first direction D1.

The first lower contact electrode 195a and the lower contact via 197 may include at least one of a metal, a metal alloy, conductive metal nitride, conductive metal carbide, conductive metal oxide, conductive metal carbonitride, and a two-dimensional (2D) material. The metal may include at least one of titanium (Ti), tantalum (Ta), tungsten (W), nickel (Ni), cobalt (Co), and platinum (Pt). The conductive metal nitride may include at least one of titanium nitride (TiN), tantalum nitride (TaN), tungsten nitride (WN), nickel nitride (NiN), cobalt nitride (CoN), and platinum nitride (PtN).

In embodiments, the first lower contact electrode 195a may be connected to the first source/drain pattern 151. The first lower contact electrode 195a may include a portion that is in contact with a lower region of the first source/drain pattern 151.

In embodiments, the first lower contact electrode 195a may include a material having a larger coefficient of thermal expansion than that of a material included in the first source/drain pattern 151. In embodiments, the first lower contact electrode 195a may include a material having a larger coefficient of thermal expansion than that of silicon (Si). For example, the first lower contact electrode 195a may include at least one of tungsten (W) and molybdenum (Mo). Because an effect of the first lower contact electrode 195a including a material having a higher coefficient of thermal expansion than that of a material included in the first source/drain pattern 151 is the same as that of the upper contact electrode 191, a detailed description thereof will be omitted.

The second power rail 199b may be disposed within the lower insulating layer 173. The second power rail 199b may be configured to provide electric power to at least one of the source/drain patterns 150. For example, the second power rail 199b may be connected to an external input power source or an output power source to provide the electric power to at least one of the source/drain patterns 150. For example, the second power rail 199b may be connected to a ground. In embodiments, the second power rail 199b may be disposed at a level lower than that of a lower surface of the source/drain pattern 150 and that of a lower surface of the gate structure GS. For example, the second power rail 199b may form at least a portion of a back side power delivery network (BSPDN). Referring to FIG. 2 and FIG. 3, the second power rail 199b may extend along the first direction D1. However, the present disclosure is not limited thereto, and the second power rail 199b may extend along the second direction D2.

In embodiments, the second power rail 199b may be connected to at least one of the N-type transistor structures. Referring to FIG. 2 and FIG. 3, the second power rail 199b may be connected to at least one of the first source/drain patterns 151. That is, in the semiconductor device according to embodiments, at least one of the first source/drain patterns 151 may be commonly connected to the first power rail 199a and the second power rail 199b. In embodiments, the second power rail 199b may be connected to the same power source as that of the first power rail 199a. Alternatively, in embodiments, the second power rail 199b may be connected to a power source having the same level of voltage as that of the first power rail 199a.

The lower contact via 197 and the first lower contact electrode 195a may be disposed between the second power rail 199b and the first source/drain pattern 151. The second power rail 199b may be electrically connected to the lower region of the first source/drain pattern 151 by the lower contact via 197 and the first lower contact electrode 195a.

The second power rail 199b may include a conductive material. For example, the second power rail 199b may include the same material as those of the first power rail 199a and the third power rail 199c, but the present disclosure is not limited thereto.

As described with reference to FIGS. 1 to 4, in the semiconductor device according to embodiments, at least one of the source/drain patterns 150 may be connected to the FSPDN and the BSPDN together. In embodiments, at least one of the first source/drain patterns 151 may be commonly connected to the first power rail 199a and the second power rail 199b. According to embodiments, at least one of the first source/drain patterns 151 may be connected to a front side power rail and a back side power rail together, and a resistance associated with the power rail may be reduced so that an electrical characteristic of the semiconductor device according to embodiments is improved.

In the semiconductor device according to embodiments, the second source/drain patterns 152 may be connected to only one of the FSPDN and the BSPDN. For example, the second source/drain patterns 152 may be connected to the FSPDN (e.g., the third power rail 199c), and may not be connected to the BSPDN. That is, the semiconductor device according to embodiments may not include the second source/drain pattern 152 connected to both the front side power rail and the back side power rail.

In the semiconductor device according to embodiments, a structure in which the FSPDN and the BSPDN are connected together to the source/drain pattern 150 may be selectively applied to the first source/drain pattern 151 including an N-type impurity. In contrast, if the FSPDN and the BSPDN are applied together to the second source/drain pattern 152 including a P-type impurity, a tensile stress induced in the channel patterns by the lower contact electrode may cause a decrease in mobility of the P-type transistor structure. The semiconductor device according to embodiments may not include a structure in which the FSPDN and the BSPDN are connected together to the second source/drain pattern 152 including the P-type impurity. According to embodiments, a structure in which the FSPDN and the BSPDN are connected together to the source/drain pattern 150 may be selectively applied to the N-type transistor structure, so that an electrical characteristic of the semiconductor device according to embodiments is improved.

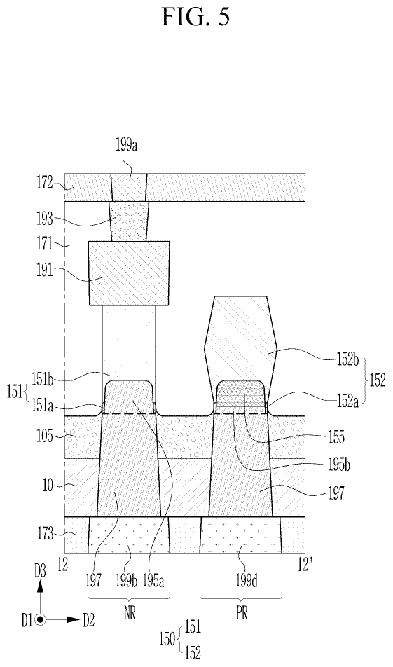

FIG. 5 is a view for describing a semiconductor device according to embodiments. FIG. 5 may correspond to a cross-section cut along a line I2-I2′ of FIG. 1 of the semiconductor device according to embodiments. Because the semiconductor device illustrated in FIG. 5 has a portion that is the same as those of the previous embodiments, a difference between the semiconductor device of FIG. 5 and the previous embodiments will be mainly described below. For example, the semiconductor device according to embodiments in which the second source/drain pattern 152 is connected to the BSPDN may be partially different from the previous embodiments.

Referring to FIG. 5, the semiconductor device according to embodiments may further include a fourth power rail 199d disposed at one side of the second power rail 199b. The fourth power rail 199d may be disposed within the lower insulating layer 173. The fourth power rail 199d may be configured to provide electric power to at least one of the source/drain patterns 150. In embodiments, the fourth power rail 199d may be disposed at a level lower than that of a lower surface of the source/drain pattern 150 and that of a lower surface of the gate structure GS. For example, the fourth power rail 199d may form at least a portion of a back side power delivery network (BSPDN).

The fourth power rail 199d may be connected to the second source/drain pattern 152. In embodiments, the fourth power rail 199d may provide electric power to the second source/drain pattern 152.

The fourth power rail 199d may include a conductive material. In embodiments, the fourth power rail 199d may include the same material as that of the second power rail 199b.

The semiconductor device according to embodiments may include a second lower contact electrode 195b and the lower contact via 197 disposed between the fourth power rail 199d and the second source/drain pattern 152. The second lower contact electrode 195b and the lower contact via 197 may electrically connect the second source/drain pattern 152 to the fourth power rail 199d.

In embodiments, the second lower contact electrode 195b may include a conductive material. For example, the second lower contact electrode 195b may include the same material as that of the first lower contact electrode 195a. For example, the second lower contact electrode 195b may include at least one of tungsten (W) and molybdenum (Mo).

The semiconductor device according to embodiments may further include a first connection pattern 155 disposed between the second source/drain pattern 152 and the second lower contact electrode 195b. The first connection pattern 155 may be disposed below the second source/drain pattern 152. In embodiments, at least some regions of an upper surface and a side surface of the first connection pattern 155 may be in contact with the second source/drain pattern 152.

In a manufacturing process of the semiconductor device according to embodiments, some regions of the substrate 10 and some regions of the lower pattern BP overlapping the second source/drain pattern 152 in the third direction D3 may be etched to form the second lower contact electrode 195b and the lower contact via 197. In this case, a portion of a lower region of the second source/drain pattern 152 may be etched together with some regions of the substrate 10 and some regions of the lower pattern BP. In embodiments, the first connection pattern 155 may fill a region where a portion of the lower region of the second source/drain pattern 152 is etched.

The first connection pattern 155 may be a pattern grown by an epitaxial growth method. In embodiments, the first connection pattern 155 may include a semiconductor material. In embodiments, the first connection pattern 155 may include a material having a larger lattice constant than that of a material included in the second source/drain pattern 152. For example, the first connection pattern 155 may include a material having a larger lattice constant than that of silicon (Si) or silicon germanium (SiGe). As an example, the first connection pattern 155 may include germanium (Ge).

In embodiments, the first connection pattern 155 may include silicon germanium (SiGe). In this case, a content of the germanium (Ge) included in the first connection pattern 155 may be greater than a content of germanium (Ge) included in the second source/drain pattern 152. In this case, a content (e.g., at %) of the germanium (Ge) within the first connection pattern 155 may be a content (e.g., at %) of the germanium with respect to 100 at % of the first connection pattern 155. A content (e.g., at %) of the germanium within the second source/drain pattern 152 may be a content (e.g., at %) of the germanium with respect to 100 at % of the second source/drain pattern 152.

If the first connection pattern 155 includes a material having a larger lattice constant than that of the material included in the second source/drain pattern 152, a compressive stress may be induced in the first direction D1 in the channel patterns 110a, 110b, 110c, and 110d. If the compressive stress is induced in the channel patterns 110a, 110b, 110c, and 110d, an interval between lattices of a material included in the channel patterns 110a, 110b, 110c, and 110d may be reduced. In this case, mobility of holes that are majority carriers may be increased during an on-operation of the P-type transistor structure so that current driving capability is improved during an on-operation of the semiconductor device.

In embodiments, the first connection pattern 155 may be in contact with the second source/drain pattern 152. The second source/drain pattern 152 may be disposed in the PMOSFET region PR. In embodiments, the second source/drain pattern 152 may include silicon germanium (SiGe). The second source/drain pattern 152 may be doped with a P-type impurity. For example, the second source/drain pattern 152 may be doped with at least one of boron (B), gallium (Ga), and indium (In).

Unlike embodiments illustrated in FIG. 5, if the second lower contact electrode 195b is in direct contact with the second source/drain pattern 152, a tensile stress may be induced in the first direction D1 in the channel patterns 110a, 110b, 110c, and 110d, and in this case, the mobility of the holes that are majority carriers of the P-type transistor structure may be decreased. In embodiments, because the first connection pattern 155 is disposed between the second source/drain pattern 152 and the second lower contact electrode 195b, a decrease in mobility by the second lower contact electrode 195b may be compensated, and an electrical characteristic of the semiconductor device according to embodiments may be improved.

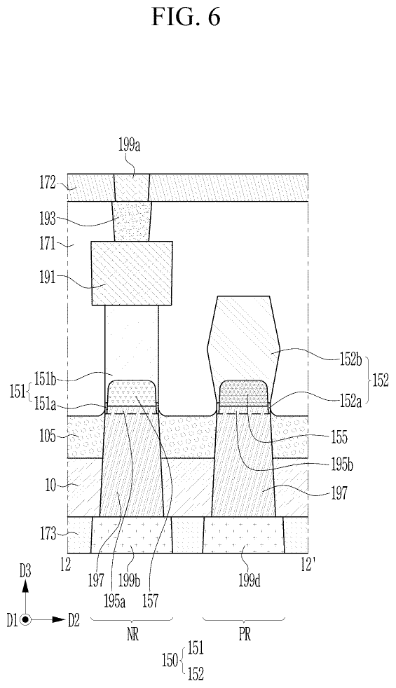

FIG. 6 is a view for describing a semiconductor device according to embodiments. FIG. 6 may correspond to a cross-section cut along a line I2-I2′ of FIG. 1 of the semiconductor device according to embodiments. Because the semiconductor device illustrated in FIG. 6 has a portion that is the same as those of the previous embodiments, a difference between the semiconductor device of FIG. 6 and the previous embodiments will be mainly described below. For example, the semiconductor device according to embodiments including a second connection pattern 157 may be partially different from the previous embodiments.

Referring to FIG. 6, the semiconductor device according to embodiments may further include the second connection pattern 157 disposed between the first lower contact electrode 195a and the first source/drain pattern 151. The second connection pattern 157 may be disposed below the first source/drain pattern 151. In embodiments, at least some regions of upper and side surfaces of the second connection pattern 157 may be in contact with the first source/drain pattern 151.

In a manufacturing process of the semiconductor device according to embodiments, some regions of the substrate 10 and some regions of the lower pattern BP overlapping the first source/drain pattern 151 in the third direction D3 may be etched to form the first lower contact electrode 195a and the lower contact via 197. In this case, a portion of a lower region of the first source/drain pattern 151 may be etched together with some regions of the substrate 10 and some regions of the lower pattern BP. In embodiments, the second connection pattern 157 may fill a region where a portion of the lower region of the first source/drain pattern 151 is etched.

The second connection pattern 157 may be a pattern grown by an epitaxial growth method. In embodiments, the second connection pattern 157 may include a semiconductor material. In embodiments, the second connection pattern 157 may include a material having a smaller lattice constant than that of a material included in the first source/drain pattern 151. For example, the second connection pattern 157 may include a material having a smaller lattice constant than that of silicon (Si). For example, the second connection pattern 157 may include silicon carbide (SiC) or carbon (C), but the present disclosure is not limited thereto.

If the second connection pattern 157 includes a material having a smaller lattice constant than that of the material included in the first source/drain pattern 151, a tensile stress may be induced in the first direction D1 in the channel patterns 110a, 110b, 110c, and 110d. Accordingly, mobility of electrons may be increased during an on-operation of the N-type transistor structure so that current driving capability is improved during an on-operation of the semiconductor device.

In embodiments, because the second connection pattern 157 is disposed between the first source/drain pattern 151 and the first lower contact electrode 195a, a tensile stress may be induced in the first direction D1 in the channel patterns 110a, 110b, 110c, and 110d, so that an electrical characteristic of the semiconductor device according to embodiments is improved.

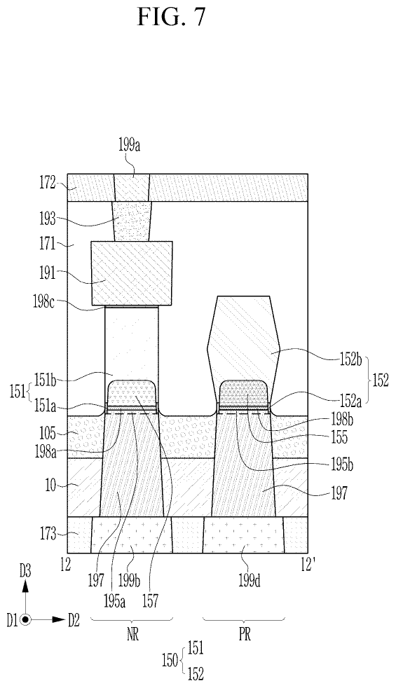

FIG. 7 is a view for describing a semiconductor device according to embodiments. FIG. 7 may correspond to a cross-section cut along a line I2-I2′ of FIG. 1 of the semiconductor device according to embodiments. Because the semiconductor device illustrated in FIG. 7 has a portion that is the same as those of the previous embodiments, a difference between the semiconductor device of FIG. 7 and the previous embodiments will be mainly described below. For example, the semiconductor device according to embodiments including silicide layers 198a, 198b, and 198c may be partially different from the previous embodiments.

Referring to FIG. 7, the semiconductor device according to embodiments may include a first silicide layer 198a, a second silicide layer 198b, and a third silicide layer 198c. The first silicide layer 198a may be disposed between the first lower contact electrode 195a and the second connection pattern 157. The first silicide layer 198a may be in contact with a lower surface of the second connection pattern 157 and an upper surface of the first lower contact electrode 195a.

The second silicide layer 198b may be disposed between the second lower contact electrode 195b and the first connection pattern 155. The second silicide layer 198b may be in contact with a lower surface of the first connection pattern 155 and an upper surface of the second lower contact electrode 195b.

The third silicide layer 198c may be disposed between the upper contact electrode 191 and the first source/drain pattern 151. The third silicide layer 198c may be in contact with at least some regions of a lower surface of the upper contact electrode 191 and an upper surface of the first source/drain pattern 151.

In embodiments, the silicide layers 198a, 198b, and 198c may be metal silicide layers. For example, the silicide layers 198a, 198b, and 198c may include at least one of tungsten silicide (WSi), nickel silicide (NiSi), and/or titanium silicide (TiSi).

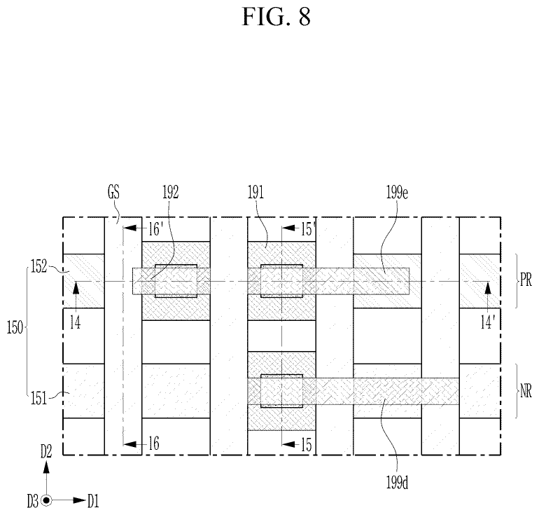

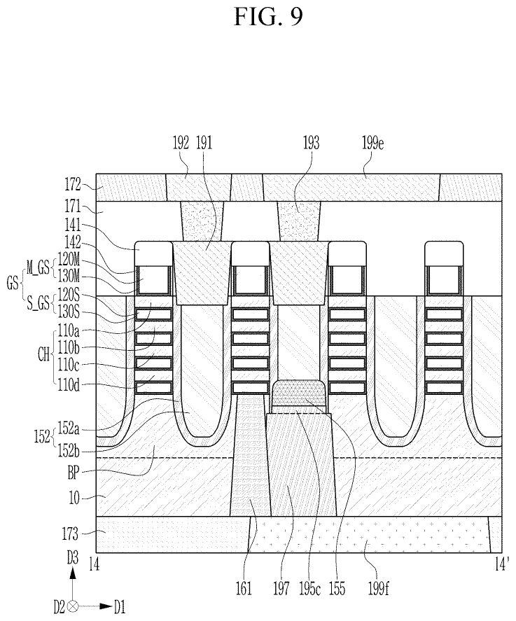

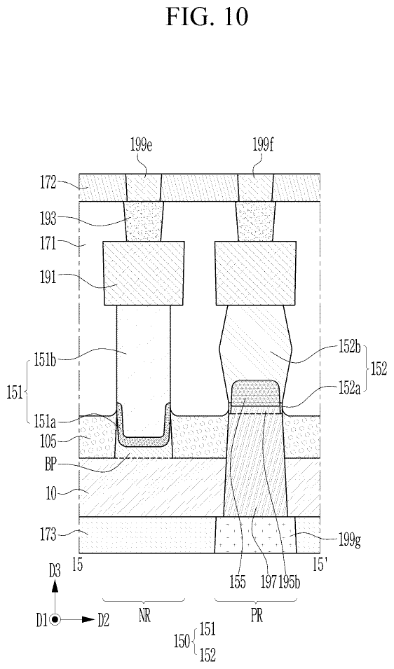

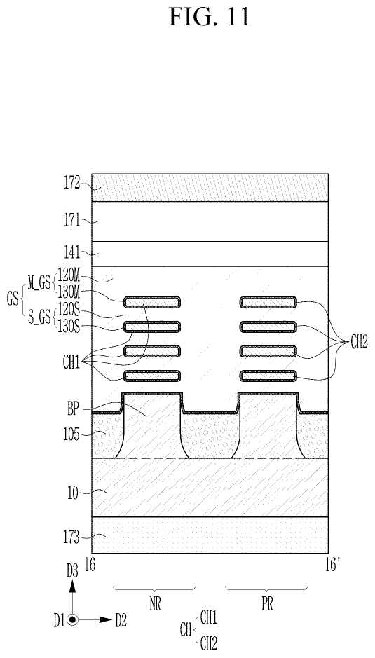

FIGS. 8 to 11 are views for describing semiconductor devices according to embodiments. Specifically, FIG. 8 is a plan view showing the semiconductor device according to embodiments, FIG. 9 is a cross-sectional view of the semiconductor device along a line I4-I4′ of FIG. 8, FIG. 10 is a cross-sectional view of the semiconductor device along a line I5-I5′ of FIG. 8, and FIG. 11 is a cross-sectional view of the semiconductor device along a line I6-I6′ of FIG. 8. A difference between the semiconductor devices of FIGS. 8 to 11 and the previous embodiments will be mainly described below. For example, the semiconductor device according to embodiments in which a second source/drain pattern 152 is connected to a FSPDN and a BSPDN together may be partially different from the previous embodiments.

Referring to FIGS. 8 to 11, the semiconductor device according to embodiments may include a substrate 10, a first channel structure CH1 and a second channel structure CH2 disposed above the substrate, a gate structure GS surrounding the first channel structure CH1 and the second channel structure CH2, first source/drain patterns 151 connected to opposite sides of the first channel structure CH1, second source/drain patterns 152 connected to opposite sides of the second channel structure CH2, a fifth power rail 199e connected to an upper region of at least one of the first source/drain patterns 151, and a sixth power rail 199f and a seventh power rail 199g each connected to an upper region and a lower region of at least one of the second source/drain patterns 152. In embodiments, a first connection pattern 155 may be disposed between the second source/drain pattern 152 and the seventh power rail 199g.

In embodiments, because a structure, a physical property, a connection relationship with peripheral components, and a function of each of the fifth power rail 199e, the sixth power rail 199f, and the seventh power rail 199g are similar to a structure, a physical property, a connection relationship with peripheral components, and a function of each of the third power rail 199c, the first power rail 199a, and the second power rail 199b of embodiments illustrated in FIGS. 1 to 4, a detailed description thereof will be omitted. In embodiments, because the first connection pattern 155 is the same as the first connection pattern 155 described with reference to FIG. 5, a detailed description thereof will be omitted.

In embodiments, the sixth power rail 199f and the seventh power rail 199g may be connected to a P-type transistor structure. Referring to FIG. 9 and FIG. 10, the sixth power rail 199f and the seventh power rail 199g may be connected to the second source/drain pattern 152. That is, in the semiconductor device according to embodiments, the second source/drain pattern 152 may be commonly connected to the sixth power rail 199f and the seventh power rail 199g. In embodiments, the sixth power rail 199f and the seventh power rail 199g may be connected to the same power source. In embodiments, the sixth power rail 199f and the seventh power rail 199g may be connected to a power source having the same level of voltage.

According to embodiments, the second source/drain pattern 152 may be connected to a front side power rail and a back side power rail together, and a resistance associated with the power rail may be reduced so that an electrical characteristic of the semiconductor device according to embodiments is improved.

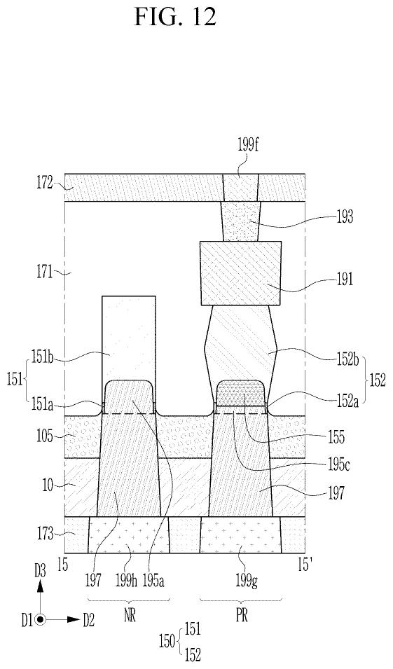

FIG. 12 is a view for describing a semiconductor device according to embodiments. Specifically, FIG. 12 may correspond to a cross-section cut along a line I5-I5′ of FIG. 8 of the semiconductor device according to embodiments. Because the semiconductor device illustrated in FIG. 12 has a portion that is the same as those of the previous embodiments, a difference between the semiconductor device of FIG. 12 and the previous embodiments will be mainly described below. For example, the semiconductor device according to embodiments in which the second source/drain pattern 152 is connected to the FSPDN and the BSPDN together and a first source/drain pattern 151 is connected to the BSPDN may be partially different from the previous embodiments.

Referring to FIG. 12, the semiconductor device according to embodiments may further include an eighth power rail 199h disposed at one side of the seventh power rail 199g. The eighth power rail 199h may be disposed within a lower insulating layer 173. The eighth power rail 199h may provide electric power to at least one of the first source/drain patterns 151. In embodiments, the eighth power rail 199h may be disposed at a level lower than that of a lower surface of a source/drain pattern 150 and that of a lower surface of the gate structure GS. For example, the eighth power rail 199h may form at least a portion of the back side power delivery network (BSPDN).

The eighth power rail 199h may include a conductive material. In embodiments, the eighth power rail 199h may include the same material as that of the seventh power rail 199g.

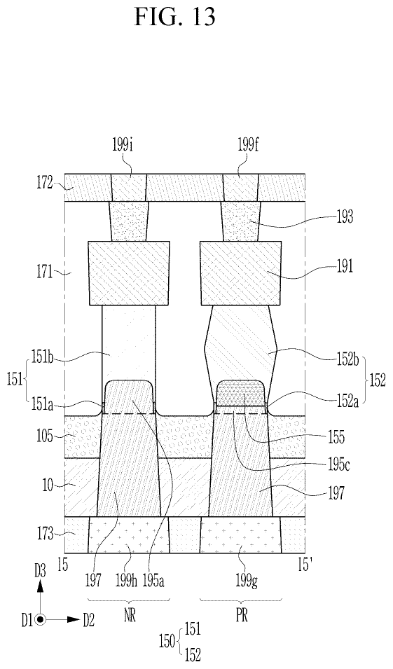

FIG. 13 is a view for describing a semiconductor device according to embodiments. Specifically, FIG. 13 may correspond to a cross-section cut along the line I5-I5′ of FIG. 8 of the semiconductor device according to embodiments. Because the semiconductor device illustrated in FIG. 13 has a portion that is the same as those of the previous embodiments, a difference between the semiconductor device of FIG. 13 and the previous embodiments will be mainly described below. For example, the semiconductor device according to embodiments in which at least one of the first source/drain patterns 151 and at least one of the second source/drain patterns 152 are connected to the FSPDN and the BSPDN together may be partially different from the previous embodiments.

Referring to FIG. 13, the semiconductor device according to embodiments may further include a ninth power rail 199i connected to the first source/drain pattern 151 compared with the semiconductor device described with reference to FIG. 12. Referring to FIG. 13, the ninth power rail 199i may be connected to an upper region of the first source/drain pattern 151.

In embodiments, the eighth power rail 199h and the ninth power rail 199i may be connected to an N-type transistor structure. Referring to FIG. 13, the eighth power rail 199h and the ninth power rail 199i may be connected to the first source/drain pattern 151. That is, in the semiconductor device according to embodiments, the first source/drain pattern 151 may be commonly connected to the eighth power rail 199h and the ninth power rail 199i. In embodiments, the eighth power rail 199h and the ninth power rail 199i may be connected to the same power source. In embodiments, the eighth power rail 199h and the ninth power rail 199i may be connected to a power source having the same level of voltage. The semiconductor device according to embodiments may include the first source/drain pattern 151 in which the FSPDN and the BSPDN are together connected and the second source/drain pattern 152 in which the FSPDN and the BSPDN are together connected, so that so that an electrical characteristic of the semiconductor device according to embodiments is improved.

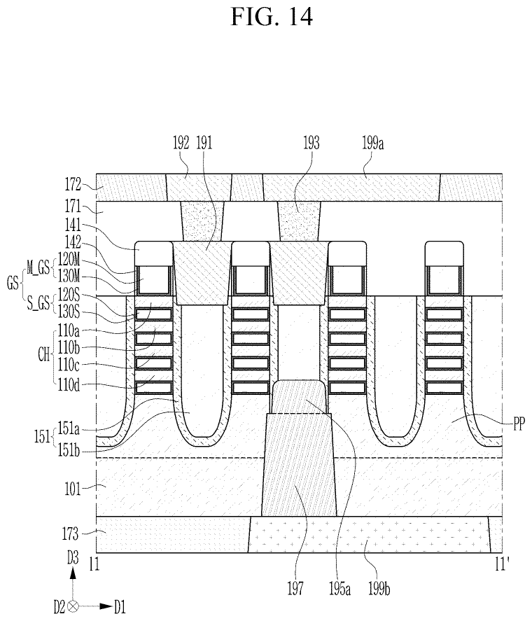

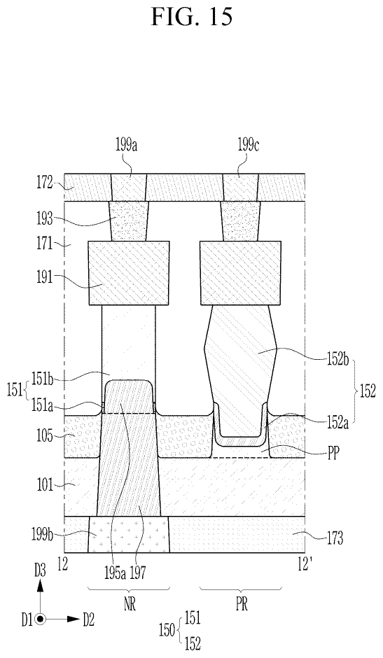

FIG. 14 and FIG. 15 are views for describing semiconductor devices according to embodiments. Specifically, FIG. 14 may correspond to a cross-section cut along the line I1-I1′ of FIG. 1, and FIG. 15 may correspond to a cross-section cut along the line I2-I2′ of FIG. 1. A difference between semiconductor devices of FIG. 14 and FIG. 15 and the previous embodiments will be mainly described below. For example, the semiconductor device according to embodiments including a base insulating layer 101 and a protruding pattern PP may be partially different from the previous embodiments.

Referring to FIG. 14 and FIG. 15, the semiconductor device according to embodiments may include the base insulating layer 101 and the protruding pattern PP. For example, the base insulating layer 101 and the protruding pattern PP may be disposed at positions of the substrate 10 and the lower pattern BP described with reference to FIGS. 1 to 4.

The base insulating layer 101 may be an insulating substrate. The base insulating layer 101 may include oxide, nitride, oxynitride, or a combination thereof. For example, the base insulating layer 101 may include silicon oxide (SiO₂). The base insulating layer 101 is illustrated as a single film, but this is only for convenience of description and the present disclosrue is not limited thereto. The base insulating layer 101 may be formed by etching the substrate 10 of FIG. 5 described with reference to FIGS. 1 to 4 and then filling the etched portion with an insulating material.

In FIG. 14 and FIG. 15, the base insulating layer 101 is illustrated as a single layer, but the base insulating layer 101 may be formed of two or more layers. In this case, the two or more layers may include different insulating materials, or may include the same insulating material.

The semiconductor device according to embodiments may further include a plurality of protruding patterns PP disposed to be spaced apart from each other along the second direction D2. The protruding patterns PP may extend long in the first direction D1. The protruding patterns PP may be disposed to be spaced apart from each other along the second direction D2. For example, the protruding patterns PP may be disposed in a region where a PMOS is formed. As another example, the protruding patterns PP may be disposed in a region where an NMOS is formed. For example, in FIG. 14 and FIG. 15, the PMOS may be formed at two protruding patterns PP disposed at the left side, and the NMOS may be formed at two protruding patterns PP disposed at the right side, but the present disclosure is not limited thereto. The protruding patterns PP may be formed by etching the lower patterns BP described with reference to FIGS. 1 to 4 and then filling the etched portion with an insulating material.

In the semiconductor device according to embodiments, the substrate 10 and the lower pattern BP may be replaced with the base insulating layer 101 and the protruding pattern PP, so that a leakage current is prevented from flowing between two adjacent source/drain patterns 150. The semiconductor device according to embodiments may not include an insulating pattern 161 described with reference to FIGS. 1 to 4.

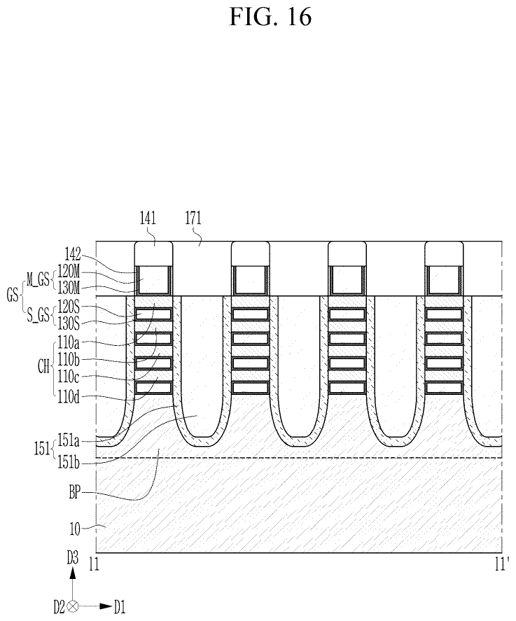

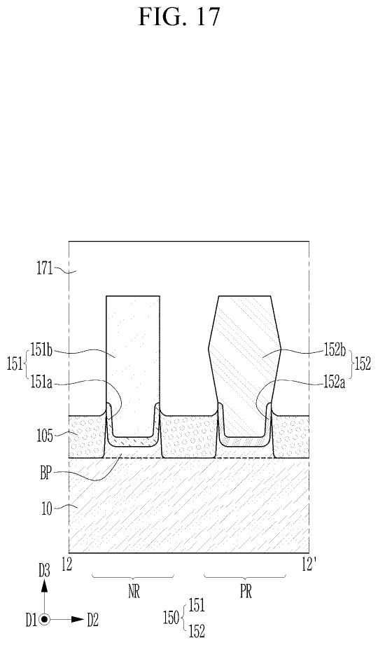

FIGS. 16 to 33 are views for describing a method for manufacturing a semiconductor device according to embodiments. FIGS. 16, 18, 20, 22, 24, 25, 26, 28, 30, and 32 are cross-sectional views corresponding to a region cut along the line I1-I1′ of FIG. 1, and FIGS. 17, 19, 21, 23, 27, 29, 31, and 33 are cross-sectional views corresponding to a region cut along the line I2-I2′ of FIG. 1.

As illustrated in FIG. 16 and FIG. 17, the lower pattern BP on the substrate 10, the field insulating layer 105 disposed at opposite sides of the lower pattern BP, the channel structures CH disposed above the lower pattern BP, the gate structures GS surrounding the channel structures CH, and the source/drain patterns 150 respectively connected to opposite sides of the channel structures CH may be formed.

First, the lower pattern BP may be formed on the substrate 10, and sacrificial layers and the channel patterns 110a, 110b, 110c, and 110d may be alternately stacked above the lower pattern BP. The field insulating layer 105 may be formed at opposite sides of the lower pattern BP. In embodiments, the substrate 10 may be a silicon-on-insulator (SOI) or bulk silicon. Alternatively, the substrate 10 may be a silicon substrate, or may include another material such as silicon germanium (SiGe), a silicon germanium on insulator (SGOI), indium antimony, a lead telluride compound, indium arsenide, indium phosphide, gallium arsenide, or gallium antimony, but the present disclosure is not limited thereto.

Next, after some regions of the sacrificial layers and the channel patterns 110a, 110b, 110c, and 110d are etched, the source/drain patterns 150 may be formed using epitaxial growth. Next, after the sacrificial layers are removed, the gate structures GS may be formed in a region where the sacrificial layers are disposed. Next, the source/drain patterns 150 and the interlayer insulating layer 171 and the capping layer 141 covering the gate structure GS may be formed.

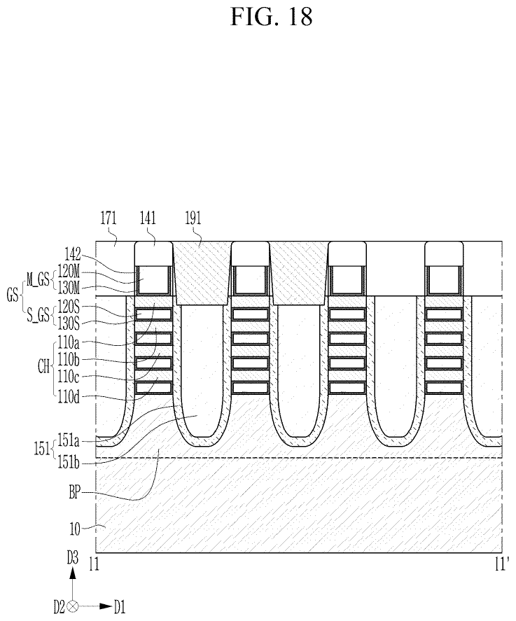

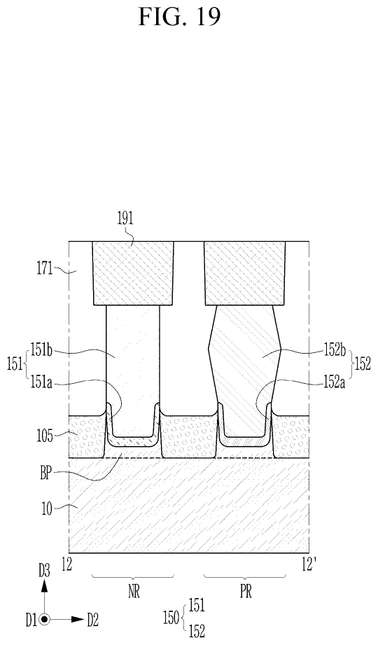

As illustrated in FIG. 18 and FIG. 19, the upper contact electrode 191 may be formed on the source/drain pattern 150. First, some regions of the interlayer insulating layer 171 overlapping the source/drain pattern 150 in the third direction D3 may be etched by a photo and etching process. Thereafter, a conductive material may be deposited in a region where the interlayer insulating layer 171 is etched and a chemical mechanical polishing process may be performed on the deposited material to form the upper contact electrode 191 on the source/drain pattern 150 as shown in FIG. 17 and FIG. 18.

In embodiments, a process of forming the upper contact electrode 191 on the source/drain pattern 150 may be performed at a high temperature. For example, the process of forming the upper contact electrode 191 may be performed at about 300 to 500 °C. In embodiments, the upper contact electrode 191 may include a material having a larger coefficient of thermal expansion than that of a material included in the source/drain pattern 150. For example, the source/drain pattern 150 may include at least one of tungsten (W) and molybdenum (Mo). In this case, as the upper contact electrode 191 is formed on the source/drain pattern 150 and then is cooled, a tensile stress may be induced in the first direction D1 in the channel patterns 110a, 110b, 110c, and 110d. If the tensile stress is induced in the channel patterns 110a, 110b, 110c, and 110d, scattering within a lattice of electrons that are majority carriers may be decreased during an on-operation of the N-type transistor structure so that mobility of the electrons is increased.

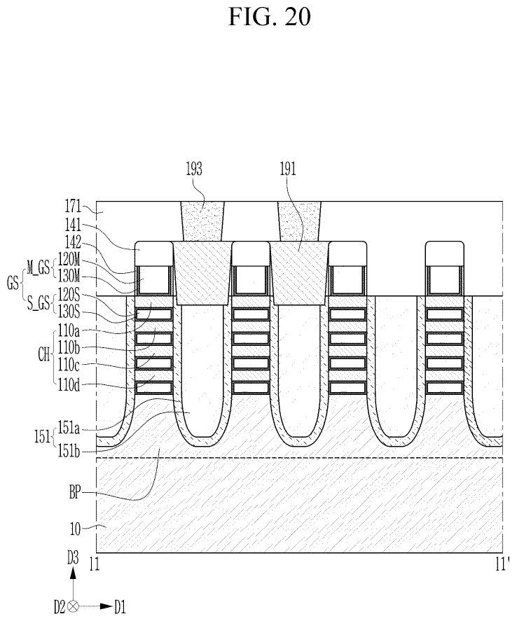

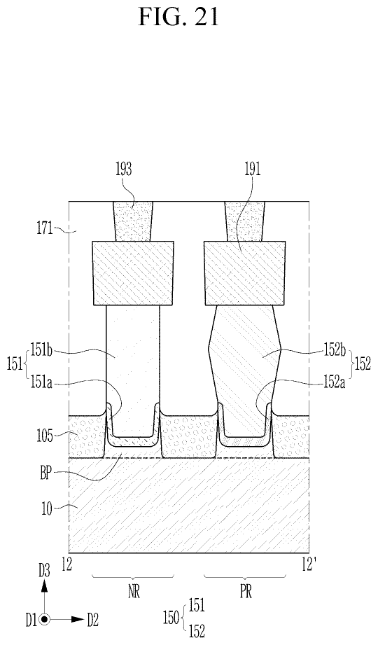

As shown in FIG. 20 and FIG. 21, the upper contact via 193 may be formed on the upper contact electrode 191. First, the interlayer insulating layer 171 may be deposited to a predetermined thickness on the source/drain pattern 150, the gate structure GS, and the upper contact electrode 191. Thereafter, some regions of the interlayer insulating layer 171 overlapping the upper contact electrode 191 in the third direction D3 may be etched by a photo and etching process. Next, after a conductive material is deposited, a chemical mechanical polishing process may be performed.

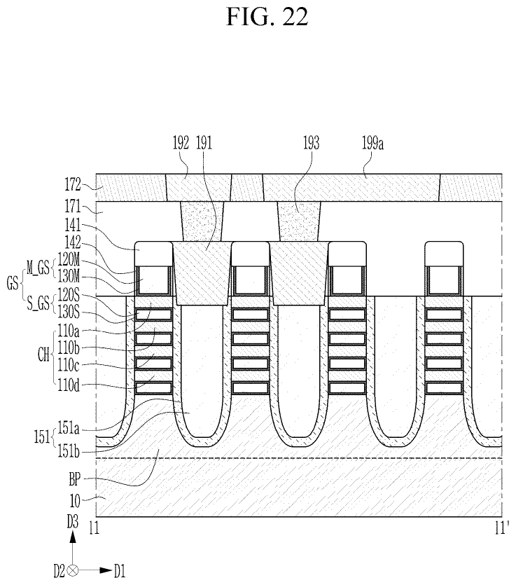

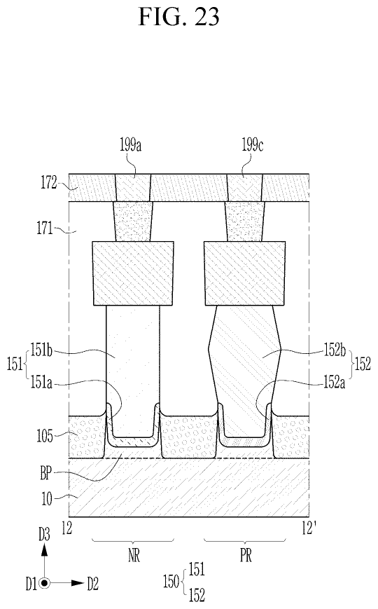

As shown in FIG. 22 and FIG. 23, the upper insulating layer 172 and the upper wiring layer 192, the first power rail 199a, and the third power rail 199c disposed inside the upper insulating layer 172 may be formed.

First, the upper insulating layer 172 may be deposited on the interlayer insulating layer 171. Next, after some regions overlapping the upper contact via 193 in the third direction D3 are etched, the etched region may be filled with a conductive material to form the upper wiring layer 192, the first power rail 199a, and the third power rail 199c. In embodiments, the upper wiring layer 192, the first power rail 199a, and the third power rail 199c may be simultaneously formed in the same process, but the present disclosure is not limited thereto.

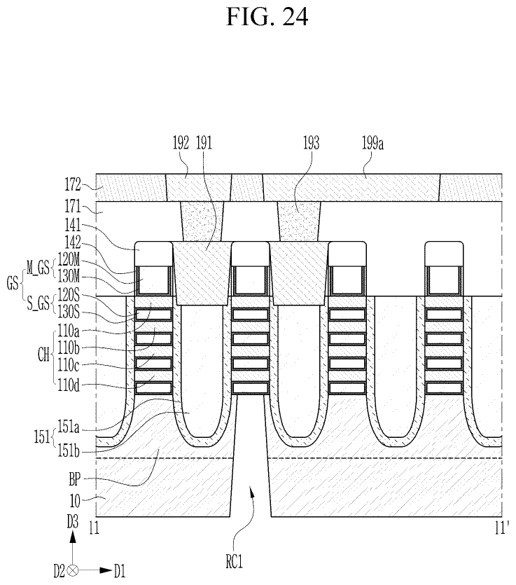

As illustrated in FIG. 24, a first recess RC1 may be formed in a lower portion of the gate structure GS. The first recess RC1 may be formed to penetrate portions of the substrate 10 and the lower pattern BP overlapping the gate structure GS in the third direction D3. The first recess RC1 may be formed by etching at least a portion of the substrate 10 and the lower pattern BP. The first recess RC1 may penetrate the substrate 10 in the third direction D3 to extend into the lower pattern BP. At least a portion of the lower surface of the gate structure GS may be exposed by the first recess RC1. Referring to FIG. 24, the first recess RC1 may have a shape in which a width in a horizontal direction thereof gradually narrows as it goes toward the lower surface of the gate structure GS. In embodiments, the first recess RC1 may be formed by a dry etching process. For example, a process of forming the first recess RC1 may be performed by a reactive ion etching (RIE) or an inductively coupled plasma (ICP). However, the present disclosure is not limited thereto, and the first recess RC1 may be formed by a wet etching process.

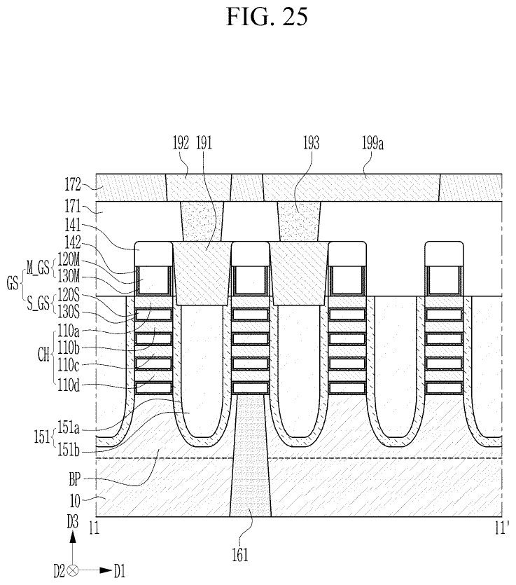

As illustrated in FIG. 25, the insulating pattern 161 may be formed below the gate structure GS. The insulating pattern 161 may fill the inside of the first recess RC1. In embodiments, the insulating pattern 161 may be formed by depositing an insulating material on the inside of the first recess RC1 and on a lower surface of the substrate 10 and then removing the insulating material deposited on the lower surface of the substrate 10. In embodiments, a process of removing the insulating material deposited on the lower surface of the substrate 10 may be performed by a chemical mechanical polishing process. In embodiments, the insulating pattern 161 may be formed by a deposition method such as sputtering, chemical vapor deposition (CVD), or atomic layer deposition (ALD).

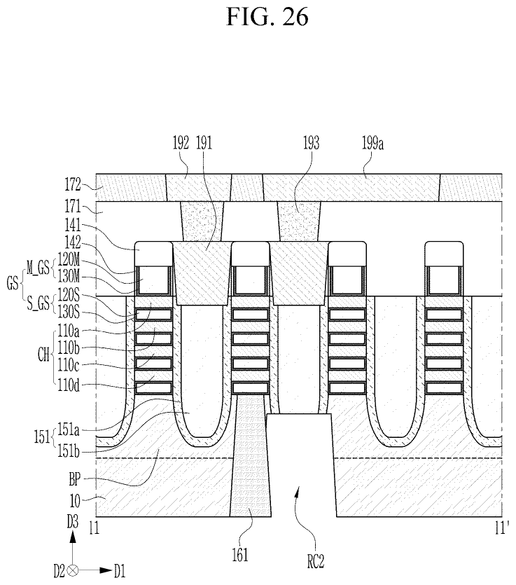

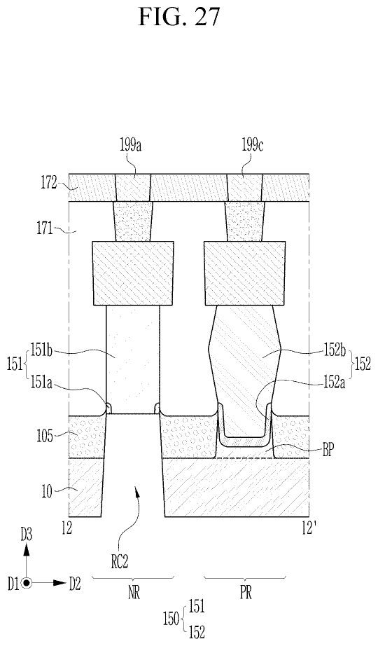

Next, as shown in FIG. 26 and FIG. 27, some regions of the substrate 10 may be etched to form a second recess RC2. For example, some regions of the substrate 10 that overlaps one of the plurality of source/drain patterns 150 in the third direction D3 may be etched by a photo and etching process. Some regions of the source/drain pattern 150 may be exposed by the second recess RC2. In embodiments, some regions of the source/drain pattern 150 may be etched together with the substrate 10. In embodiments, a process of forming the second recess RC2 may be performed by a dry etching process, but the present disclosure is not limited thereto.

Referring to FIG. 26 and FIG. 27, a width of the second recess RC2 in the first direction D1 and the second direction D2 may be wider than a width of a lower surface of the source/drain pattern 150 in the first direction D1 and the second direction D2. In embodiments, a process of etching the substrate 10 may be performed using an etching material having a higher etching selectivity with respect to the substrate 10 compared with the field insulating layer 105.

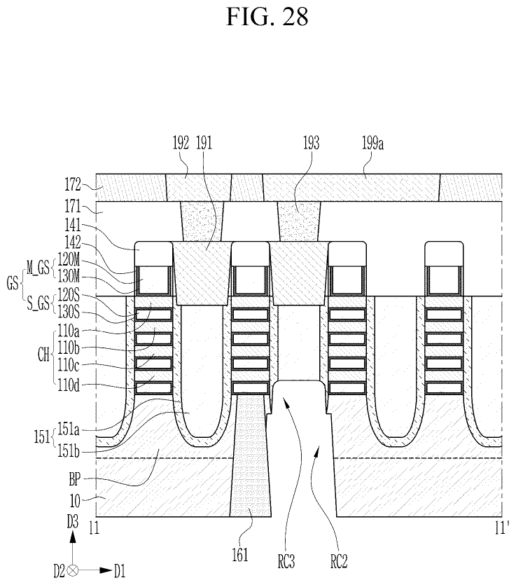

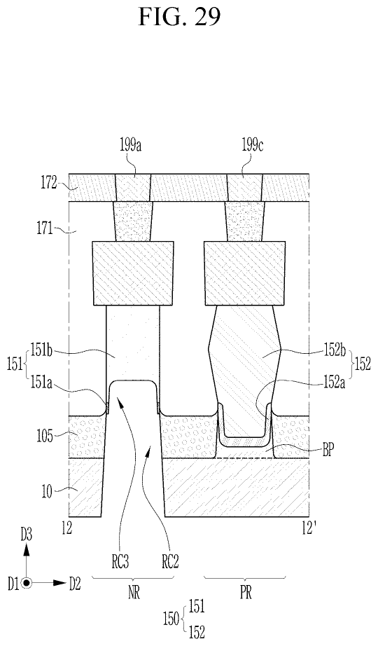

As illustrated in FIG. 28 and FIG. 29, some regions of the source/drain pattern 150 exposed by the second recess RC2 may be etched to form a third recess RC3. In embodiments, a process of forming the third recess RC3 may be performed by a self-aligned contact (SAC) process. In embodiments, the substrate 10 and the field insulating layer 105 may include an insulating material having an etching selectivity with the source/drain pattern 150. For example, a process of etching some regions of the source/drain pattern 150 exposed by the second recess RC2 may be performed using an etching material having a higher etching selectivity for the source/drain pattern 150 compared with the substrate 10 and the field insulating layer 105. In embodiments, a process of forming the third recess RC3 may be performed by a dry etching process or a wet etching process.

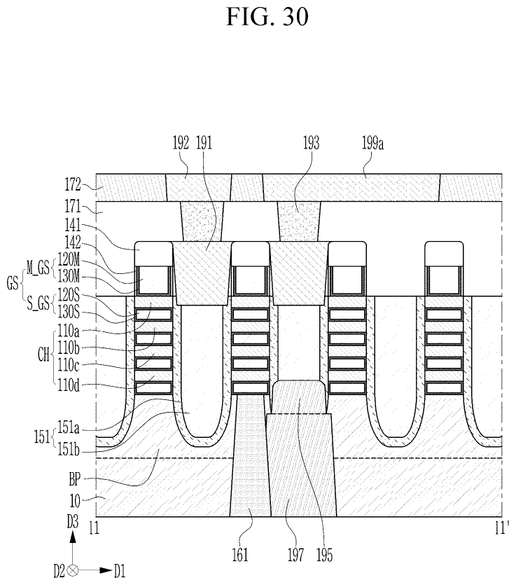

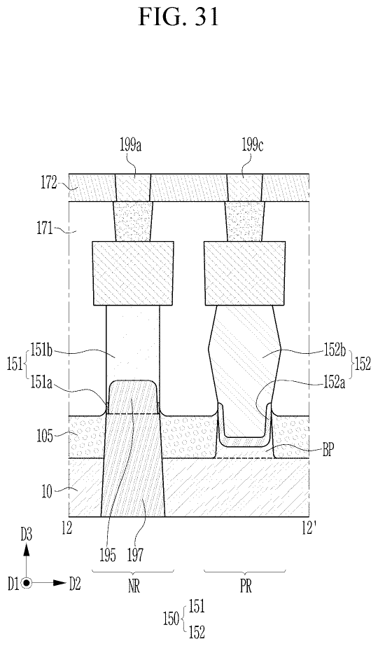

As illustrated in FIG. 30 and FIG. 31, a conductive material may be deposited inside the second recess RC2 and the third recess RC3 to form the lower contact electrode 195 and the lower contact via 197. In embodiments, the lower contact electrode 195 and the lower contact via 197 may be simultaneously formed in the same process, but the present disclosure is not limited thereto. In embodiments, a silicide layer may be further formed at an interface between the lower contact electrode 195 and the source/drain pattern 150.

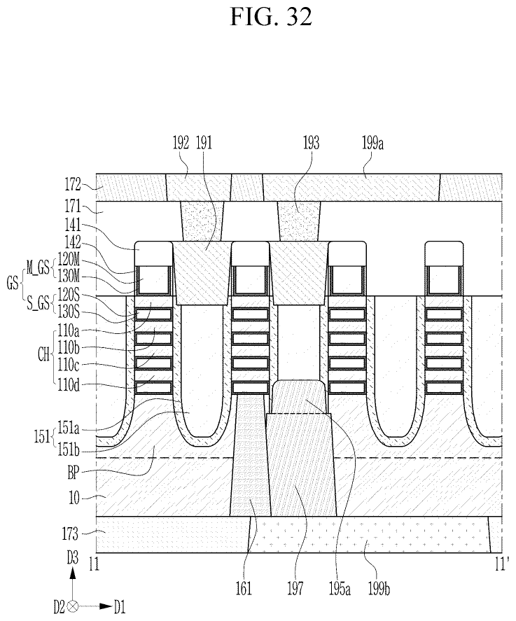

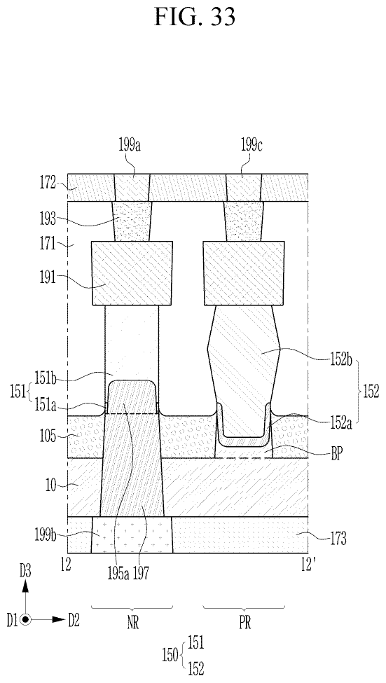

Next, as shown in FIG. 32 and FIG. 33, the lower insulating layer 173 and the second power rail 199b may be formed. First, the lower insulating layer 173 covering an entire lower surface of the substrate 10 may be formed, and some regions of the lower insulating layer 173 overlapping the lower contact via 197 in the third direction D3 may be etched to expose a lower surface of the lower contact via 197.

Subsequently, the second power rail 199b may be formed by filling a region from which a portion of the lower insulating layer 173 is removed with a conductive material.

While embodiments of the present disclosure has been described in connection with what is presently considered to be practical embodiments, it should be understood that the disclosure is not limited to the disclosed embodiments, but, on the contrary, is intended to cover various modifications and equivalent arrangements included within the spirit and scope of the appended claims.

What is claimed is:

1. A semiconductor device comprising:
a substrate;
a first channel structure and a second channel structure on the substrate;
a gate structure surrounding the first channel structure and the second channel structure;
first source/drain patterns connected to opposite sides of the first channel structure and including an N-type impurity;
second source/drain patterns connected to opposite sides of the second channel structure and including a P-type impurity;
a first power rail connected to an upper region of one of the first source/drain patterns;
a second power rail connected to a lower region of the one of the first source/drain patterns; and
a third power rail connected to an upper region or a lower region of one of the second source/drain patterns.

2. The semiconductor device of claim 1, wherein the third power rail is connected to the lower region of the one of the second source/drain patterns, and
wherein the semiconductor device further includes a first connection pattern that is disposed between the one of the second source/drain patterns and the third power rail.

3. The semiconductor device of claim 2, wherein the first connection pattern includes a material having a lattice constant larger than that of silicon (Si).

4. The semiconductor device of claim 2, wherein the first connection pattern includes germanium (Ge).

5. The semiconductor device of claim 2, wherein:
the second source/drain patterns and the first connection pattern include silicon germanium (SiGe), and a content of germanium within the first connection pattern is greater than a content of germanium within the second source/drain patterns.

6. The semiconductor device of claim 2, wherein at least a portion of an upper surface and a side surface of the first connection pattern are in contact with the one of the second source/drain patterns.

7. The semiconductor device of claim 2, further comprising:
a second lower contact electrode disposed between the first connection pattern and the third power rail; and
a silicide layer disposed between the second lower contact electrode and the first connection pattern.

8. The semiconductor device of claim 1, wherein the first power rail and the second power rail are connected to a power source having the same level of voltage.

9. The semiconductor device of claim 1, further comprising:
an upper contact electrode disposed between the one of the first source/drain patterns and the first power rail;
a lower contact via disposed between the one of the first source/drain patterns and the second power rail; and
a first lower contact electrode disposed on the lower contact via, wherein the first lower contact electrode includes a portion that is in contact with the lower region of the one of the first source/drain patterns.

10. The semiconductor device of claim 9, wherein the first source/drain patterns include silicon (Si), and
wherein the first lower contact electrode includes a material having a larger coefficient of thermal expansion than that of silicon.

11. The semiconductor device of claim 10, wherein the first lower contact electrode includes at least one of tungsten (W) and molybdenum (Mo).

12. The semiconductor device of claim 1, further comprising a second connection pattern disposed between the one of the first source/drain patterns and the second power rail.

13. The semiconductor device of claim 12, wherein at least a portion of an upper surface and a side surface of the second connection pattern are in contact with the one of the first source/drain patterns.

14. The semiconductor device of claim 12, wherein the first source/drain patterns include silicon (Si), and
wherein the second connection pattern includes a material having a lattice constant smaller than that of silicon (Si).

15. The semiconductor device of claim 12, wherein the second connection pattern includes silicon carbide (SIC).

16. A semiconductor device comprising:
a substrate;
a first channel structure and a second channel structure on the substrate;
a gate structure surrounding the first channel structure and the second channel structure;
first source/drain patterns connected to opposite sides of the first channel structure and including an N-type impurity;
second source/drain patterns connected to opposite sides of the second channel structure and including a P-type impurity;
a fourth power rail connected to an upper region or a lower region of one of the first source/drain patterns;
a fifth power rail connected to an upper region of one of the second source/drain patterns;
a sixth power rail connected to a lower region of the one of the second source/drain patterns; and
a first connection pattern disposed between the one of the second source/drain patterns and the sixth power rail.

17. The semiconductor device of claim 16, wherein the first connection pattern includes a material having a lattice constant larger than that of silicon (Si).

18. The semiconductor device of claim 16, wherein at least a portion of an upper surface and a side surface of the first connection pattern are in contact with the one of the second source/drain patterns.

19. The semiconductor device of claim 16, wherein the fifth power rail and the sixth power rail are connected to a power source having a same level of voltage.

20. A semiconductor device comprising:
a substrate;
a first channel structure and a second channel structure on the substrate;
a gate structure surrounding the first channel structure and the second channel structure;
first source/drain patterns connected to opposite sides of the first channel structure and including an N-type impurity;
second source/drain patterns connected to opposite sides of the second channel structure and including a P-type impurity;
a fifth power rail on one of the second source/drain patterns;
an upper contact via disposed between the one of the second source/drain patterns and the fifth power rail;
a sixth power rail disposed below the substrate;
a lower contact via disposed on an upper surface of the sixth power rail;
a third lower contact electrode disposed between the one of the second source/drain patterns and the lower contact via; and
a first connection pattern disposed between the one of the second source/drain patterns and the third lower contact electrode,
wherein the second source/drain patterns include silicon germanium, and the first connection pattern includes germanium.
